(19) United States
(12) Patent Application Publication
(10) Pub. No.: US 2026/0211325 A1
(43) Pub. Date: Jul. 23, 2026

(54) RADIATION-SENSITIVE COMPOSITION AND PATTERN FORMING METHOD

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 19/135,848

(22) PCT Filed: Oct. 17, 2023
(86) PCT No.: PCT/JP2023/037498

§ 371 Date: Jun. 5, 2025

(30) Foreign Application Priority Data
Dec. 26, 2022 (JP) 2022-208065

(51) Int. Cl. G03F 7/038; C08F 212/14; C08F 220/30; G03F 7/00; G03F 7/039; G03F 7/20; H10P 76/20

(52) U.S. Cl. CPC G03F 7/0388; C08F 212/24; C08F 220/301; G03F 7/039; C08F 2800/10; G03F 7/2004; G03F 7/70033; H10P 76/2041

(57) ABSTRACT

Provided are a radiation-sensitive resin composition capable of forming a resist film capable of exhibiting sensitivity and CDU performance at sufficient levels when a next-generation technology is applied, and a pattern formation method. A radiation-sensitive resin composition containing a radiation-sensitive acid generating resin containing a structural unit (I) having an acid-dissociable group and a structural unit (II) having an organic acid anion moiety and an onium cation moiety and a solvent, wherein the acid-dissociable group and the organic acid anion moiety each contain an iodine-substituted aromatic ring structure.

### BACKGROUND OF THE DISCLOSURE

### Technical Field

The present disclosure relates to a radiation-sensitive composition and a pattern forming method.

### Background Art

A photolithography technique performed using a resist composition has been utilized for formation of a fine circuit on a semiconductor device. As the representative procedure, for example, a resist pattern is formed on a substrate by generating an acid by irradiating the coating of the resist composition with radioactive ray through a mask pattern, and then generate a difference in solubility of polymer into an alkaline or organic developer between an exposed part and a non-exposed part through a reaction in the presence of the acid as a catalyst.

In the photolithography technique, pattern miniaturization is promoted by using short-wavelength radiation such as ArF excimer laser, or by combining such radiation with an immersion exposure method (liquid immersion lithography). As a next-generation technology, further short-wavelength radiation, such as an electron beam, an X-ray, and an extreme ultraviolet ray (EUV) is being utilized, and a resist material containing an acid generator with a benzene ring having an enhanced efficiency of absorbing such radiation is also being studied (Patent Document 1).

### PRIOR ART DOCUMENT

### Patent Document

Patent Document 1: JP-A-2018-5224

### SUMMARY OF THE INVENTION

### Problems to be Solved by the Invention

Even in the above-described next-generation technology, various resist performances equivalent to or higher than conventional performances are required in sensitivity and critical dimension uniformity (CDU) performance, which is an index of uniformity of a line width and a hole diameter, and the like.

An object of the present invention is to provide a radiation-sensitive resin composition capable of forming a resist film capable of exhibiting sensitivity and CDU performance at sufficient levels when a next-generation technology is applied, and a pattern formation method.

As a result of intensive research into solving the above problem, the present inventors discovered that the above object can be achieved by adopting the following configuration, and thus completed the present invention.

The present invention relates to, in one embodiment,
a radiation-sensitive resin composition containing:
a radiation-sensitive acid generating resin containing a structural unit (I) having an acid-dissociable group and a structural unit (II) having an organic acid anion moiety and an onium cation moiety; and
a solvent,
wherein the acid-dissociable group and the organic acid anion moiety each contain an iodine-substituted aromatic ring structure.

With the radiation-sensitive resin composition, a resist film satisfying sensitivity and CDU performance can be constructed. The reason for this is not clear, but can be expected as follows. Absorption of radiation such as EUV having a wavelength of 13.5 nm by iodine atoms is very large, and this increases secondary electron generation efficiency and makes the radiation-sensitive resin composition highly sensitive. Since a structure that generates an acid through irradiation with radiation is incorporated in the resin as the structural unit (II), the acid diffusion length can be appropriately controlled. In addition, since the acid-dissociable group contains the iodine-substituted aromatic ring structure, a carbocation that is considered to be generated during dissociation by an acid is stabilized, and as a result, further improvement in sensitivity can be achieved. It is presumed that resist performances as described above can be exerted due to these combined actions.

The present invention relates to, in another embodiment,
a pattern forming method, including
directly or indirectly applying the radiation-sensitive composition onto a substrate to form a resist film,
exposing the resist film to light, and
developing the exposed resist film with a developer.

Since the above-described radiation-sensitive resin composition capable of forming a resist film superior in sensitivity and CDU performance is used in the pattern formation method, a high-quality resist pattern can efficiently be formed.

### MODE FOR CARRYING OUT THE INVENTION

Hereinafter, embodiments of the present invention will be described in detail, but the present invention is not limited to these embodiments.

### <<Radiation-Sensitive Resin Composition>>

A radiation-sensitive resin composition (hereinafter also simply referred to as “composition”) according to the present embodiment contains a prescribed radiation-sensitive acid generating resin and a solvent. The composition may contain another optional component as long as the effects of the present invention are not impaired. Owing to the fact that the radiation-sensitive resin composition contains the prescribed radiation-sensitive acid generating resin, sensitivity and CDU performance can be imparted to the radiation-sensitive resin composition at high levels.

### <Radiation-Sensitive Acid Generating Resin>

The radiation-sensitive acid generating resin is an aggregate of polymers containing a structural unit (I) having an acid-dissociable group and a structural unit (II) having an organic acid anion moiety and an onium cation moiety (hereinafter, this resin is also referred to as a “base resin”), and is a component that generates an acid through exposure to light. The structural unit (I) and the structural unit (II) may be contained in the same polymer, or alternatively, the structural unit (I) may be contained in one polymer and the structural unit (II) may be contained in another polymer. It is merely required that the whole polymer constituting the radiation-sensitive acid generating resin contains the structural unit (I) and the structural unit (II). The radiation-sensitive acid generating resin may contain a structural unit other than the structural unit (I) and the structural unit (II).

The “acid-dissociable group” refers to a group that substitutes for a hydrogen atom of a carboxy group, a phenolic hydroxy group, an alcoholic hydroxy group, a sulfo group, or the like, and is dissociated by the action of an acid. An acid generated from the radiation-sensitive acid generating resin through exposure to light dissociates the acid-dissociable group in the structural unit (I) to generate a carboxy group or the like. As a result, a difference in solubility into a developer arises between the exposed portion and the unexposed portion of a resist film, making it possible to achieve pattern formation.

Thanks to the fact that the acid-dissociable group of the structural unit (I) and the organic acid anion moiety of the structural unit (II) each contain an iodine-substituted aromatic ring structure, it is possible to achieve increased sensitivity due to improvement in acid generation efficiency through secondary electron generation and improvement in ease of dissociation of the acid-dissociable group and achieve exhibition of CDU performance through control of the acid diffusion length. The radiation-sensitive acid generating resin may contain other structural units. In this case, the other structural units may contain an iodine-substituted aromatic ring structure.

The aromatic ring in the iodine-substituted aromatic ring structure is not particularly limited as long as the ring forms a ring structure having aromaticity. Examples of the aromatic ring include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, a triazine group, a carbazole ring, and a dibenzofuran ring, or combinations thereof. Among them, a benzene ring is preferable as the aromatic ring.

### (Structural Unit (I))

The structural unit (I) is a structural unit having an acid-dissociable group. The acid-dissociable group of the structural unit (I) contains the iodine-substituted aromatic ring structure. The structural unit (I) is not particularly limited as long as the structural unit (I) has an acid-dissociable group, and examples thereof include a structural unit having a tertiary alkyl ester moiety, a structural unit having a structure in which a hydrogen atom of a phenolic hydroxy group is replaced by a tertiary alkyl group, and a structural unit having an acetal linkage. The base resin may contain one type or two or more types of the structural unit (I).

The number of the iodine atoms in the iodine-substituted aromatic ring structure in the acid-dissociable group is not particularly limited, but is preferably 1, 2, or 3, and more preferably 1 or 2 from the viewpoint of sensitivity or the solubility of the base resin.

The structural unit (I) is preferably a structural unit represented by the following formula (1) (hereinafter, also referred to as a “structural unit (I-1)”).

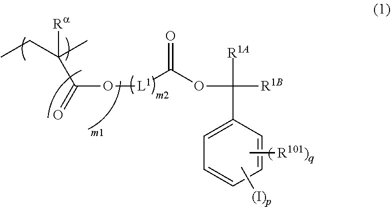

(In the formula (1),
R^{a} is a hydrogen atom, a fluorine atom, a methyl group, or a trifluoromethyl group.
L¹ is a divalent linking group.
R^{1A} and R^{1B} are each independently a monovalent chain hydrocarbon group having 1 to 10 carbon atoms or a monovalent alicyclic hydrocarbon group having 3 to 20 carbon atoms, or R^{1A} and R^{1B} taken together represent a divalent alicyclic group having 3 to 20 carbon atoms together with the carbon atom to which R^{1A} and R^{1B} are bonded.
R¹⁰¹ is a nitro group, a cyano group, a hydroxy group, an alkoxy group, or an amino group. When there are a plurality of R¹⁰¹s, the plurality of R¹⁰¹s are the same as or different from each other.
m1 and m2 are each independently 0 or 1, provided that when m1 is 1, m2 is 1.
p is an integer of 1 to 3, and q is an integer of 0 to 3, provided that p+q is 5 or less.)

Examples of the divalent linking group represented by L¹ include an alkanediyl group, a cycloalkanediyl group, an alkenediyl group, an arenediyl group, a group containing, between carbon-carbon bonds of these groups, —CO—, —CS—, —O—, —S—, —SO₂—, —NR′—, or a combination of two or more thereof, or a group obtained by combining these groups. R′ is a hydrogen atom or a monovalent hydrocarbon group having 1 to 10 carbon atoms. Some or all of hydrogen atoms of these groups may be substituted with, for example, a halogen atom such as a fluorine atom, a chlorine atom, a bromine atom, or an iodine atom; a hydroxy group; a carboxy group; a cyano group; a nitro group; an alkyl group; an alkoxy group; an alkoxycarbonyl group; an alkoxycarbonyloxy group; an acyl group; an acyloxy group, or a group obtained by substituting a hydrogen atom of such a group with a halogen atom.

The alkanediyl group is preferably an alkanediyl group having 1 to 8 carbon atoms such as a methanediyl group, an ethanediyl group, a 1,3-propanediyl group, or a 2,2-propanediyl group.

Examples of the cycloalkanediyl group include monocyclic cycloalkanediyl groups such as a cyclopentanediyl group and a cyclohexanediyl group; and polycyclic cycloalkanediyl groups such as a norbornanediyl group and an adamantanediyl group. The cycloalkanediyl group is preferably a cycloalkanediyl group having 5 to 12 carbon atoms.

Examples of the alkenediyl group include an ethenediyl group, a propenediyl group, and a butenediyl group. The alkenediyl group is preferably an alkenediyl group having 2 to 6 carbon atoms.

Examples of the arenediyl group (arylene group) include a phenylene group, a tolylene group, and a naphthylene group. The arenediyl group is preferably an arenediyl group having 6 to 15 carbon atoms.

The divalent linking group represented by L¹ is preferably an alkanediyl group or an arenediyl group, more preferably an alkanediyl group having 1 to 4 carbon atoms or an arenediyl group having 6 to 10 carbon atoms, and still more preferably a methanediyl group or a phenylene group.

Examples of the monovalent chain hydrocarbon group having 1 to 10 carbon atoms represented by R^{1A} and R^{1B} include a monovalent linear or branched saturated hydrocarbon group having 1 to 10 carbon atoms and a monovalent linear or branched unsaturated hydrocarbon group having 1 to 10 carbon atoms. Examples of the monovalent linear or branched saturated hydrocarbon group having 1 to 10 carbon atoms include alkyl groups such as a methyl group, an ethyl group, an n-propyl group, an i-propyl group, an n-butyl group, a 2-methylpropyl group, a 1-methylpropyl group, a t-butyl group, an n-pentyl group, an isopentyl group, and a neopentyl group. Examples of the monovalent linear chain or branched chain unsaturated hydrocarbon group having 2 to 10 carbon atoms include alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms represented by R^{1A} and R^{1B} include monocyclic or polycyclic saturated hydrocarbon groups and monocyclic or polycyclic unsaturated hydrocarbon groups. As the monocyclic saturated hydrocarbon group, a cyclopentyl group, a cyclohexyl group, a cycloheptyl group, and a cyclooctyl group are preferable. As the polycyclic cycloalkyl group, bridged alicyclic hydrocarbon groups such as a norbornyl group, an adamantyl group, a tricyclodecyl group, and a tetracyclododecyl group are preferable. Examples of the monocyclic unsaturated hydrocarbon group include monocyclic cycloalkenyl groups such as a cyclopropenyl group, a cyclobutenyl group, a cyclopentenyl group, and a cyclohexenyl group. Examples of the polycyclic unsaturated hydrocarbon group include polycyclic cycloalkenyl groups such as a norbornenyl group, a tricyclodecenyl group, and a tetracyclododecenyl group. It is to be noted that the bridged alicyclic hydrocarbon group refers to a polycyclic alicyclic hydrocarbon group in which two carbon atoms that compose an alicyclic ring and are not adjacent to each other are bonded by a linking group containing one or more carbon atoms.

As the divalent alicyclic group having 3 to 20 carbon atoms composed of R^{1A} and R^{1B} together with the carbon atom to which R^{1A} and R^{1B} are bonded, groups obtained by removing one hydrogen atom from the monovalent alicyclic hydrocarbon group having 3 to 20 carbon atoms can be suitably employed.

As R^{1A} and R^{1B}, a monovalent chain hydrocarbon group having 1 to 10 carbon atoms or a divalent alicyclic group having 3 to 20 carbon atoms composed of R^{1A} and R^{1B} together with the carbon atom to which R^{1A} and R^{1B} are bonded is preferable, a monovalent linear hydrocarbon group having 1 to 10 carbon atoms or a divalent alicyclic group having 5 to 10 carbon atoms is more preferable, and a methyl group, an ethyl group, a cyclopentanediyl group, or a cyclohexanediyl group is still more preferable.

Examples of the alkoxy group represented by R¹⁰¹ include alkoxy groups having 1 to 5 carbon atoms such as a methoxy group, an ethoxy group, and a propoxy group.
p is preferably 1 or 2.

Specific examples of the structural unit (I) include, but are not particularly limited to, structures represented by the following formulas (1-1) to (1-17).

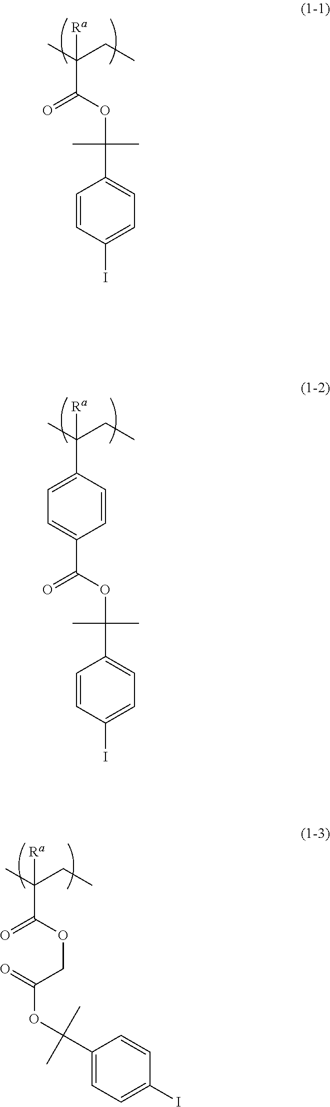

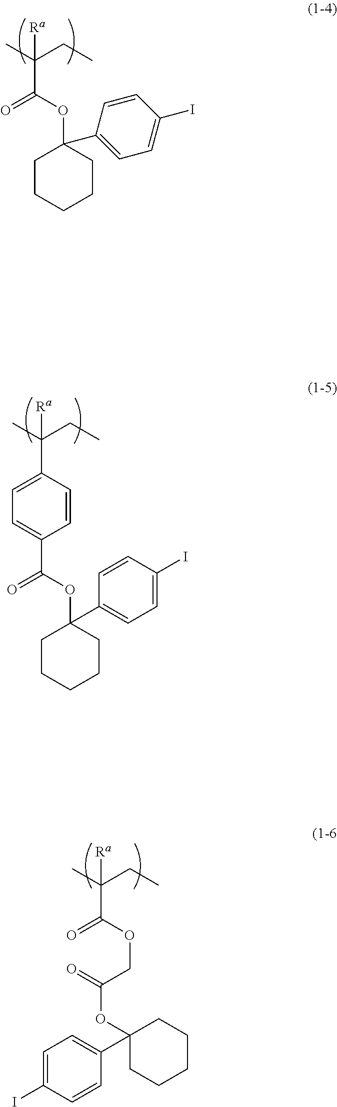

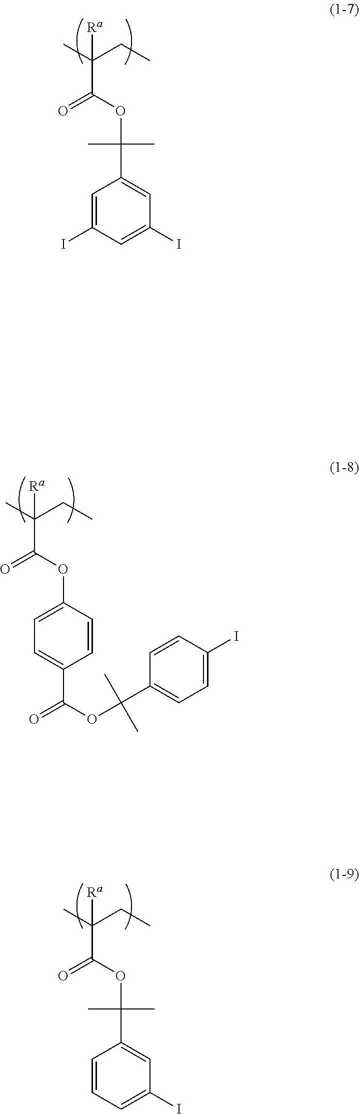

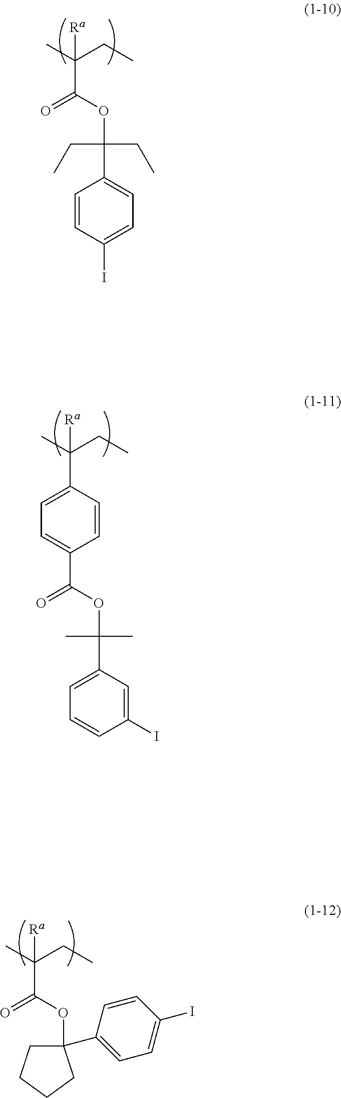

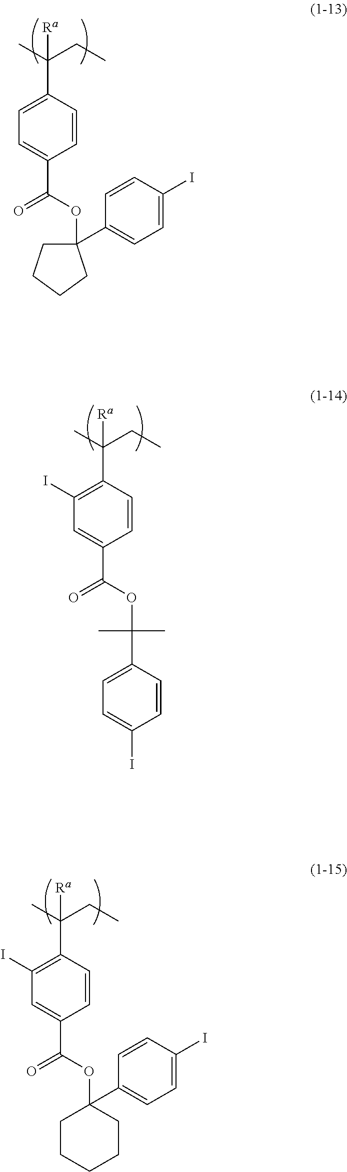

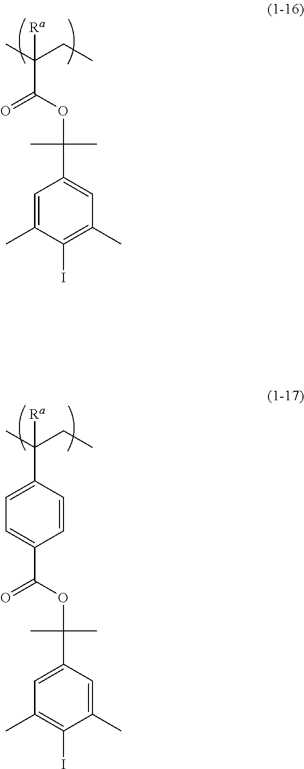

(In the formulas, R^{α} has the same meaning as in the formula (1).)

The lower limit of the content of the structural unit (I) (when a plurality of types is contained, the total content thereof is taken) is preferably 5 mol %, more preferably 8 mol %, and still more preferably 12 mol % based on all structural units composing the base resin. The upper limit of the content is preferably 60 mol %, more preferably 55 mol %, and still more preferably 50 mol %. When the content of the structural unit (I) is adjusted to within the above range, the sensitivity of the radiation-sensitive resin composition can be further improved.

### (Structural Unit (II))

The structural unit (II) has an organic acid anion moiety and an onium cation moiety. The organic acid anion moiety of the structural unit (II) contains the iodine-substituted aromatic ring structure described above. The onium cation moiety may contain the iodine-substituted aromatic ring structure described above. The form of the organic acid anion moiety and the onium cation moiety contained in the structural unit (II) of the base resin is not particularly limited, and the base resin may have the organic acid anion moiety as a side chain portion or may have the onium cation moiety as a side chain portion. Having as a side chain portion means that the corresponding organic acid anion moiety or onium cation moiety is bonded (covalently bonded) to the main chain as a side chain structure of the base resin. When the organic acid anion moiety is bonded to the main chain as a side chain structure of the base resin, the onium cation moiety is ionically bonded to the organic acid anion moiety as a counter ion of the organic acid anion moiety. On the other hand, when the onium cation moiety is bonded to the main chain as a side chain structure of the base resin, the organic acid anion moiety is ionically bonded to the onium cation moiety as a counter ion of the onium cation moiety. From the viewpoint of controlling the acid diffusion length, the base resin preferably has the organic acid anion moiety as a side chain portion.

The number of the iodine atoms in the iodine-substituted aromatic ring structure in the organic acid anion moiety is preferably 1 to 4, and more preferably 2 or 3.

The organic acid anion moiety preferably has at least one anion selected from the group consisting of a sulfonate anion, a carboxylate anion, and a sulfonimide anion. In particular, the organic acid anion moiety preferably has a sulfonate anion.

Examples of the acid generated through exposure to light may include a sulfonic acid, a carboxylic acid, and a sulfonimide corresponding to the organic acid anion.

Preferably, the organic acid anion moiety has a sulfonate anion and has a fluorine atom or a fluorinated hydrocarbon group bonded to a carbon atom adjacent to the sulfonate anion. As a result, the strength of the acid generated through exposure to light can be sufficiently enhanced to a level required for dissociation of the acid-dissociable group.

The structure of the organic acid anion moiety is not particularly limited as long as it contains an iodine-substituted aromatic ring structure. The organic acid anion moiety preferably contains —O—, —CO—, a cyclic structure, or a combination thereof. The combination also includes a structure (heterocyclic structure) in which —O— or —CO— is incorporated as a moiety forming a ring in a cyclic structure.

The cyclic structure may be any of a monocyclic ring, a polycyclic ring, or a combination thereof. The cyclic structure may be any of an alicyclic structure, an aromatic ring structure, a heterocyclic structure, or a combination thereof. In the case of the combination, the ring structure may be a structure in which ring structures are bonded through a chain structure, or two or more ring structures may form a fused ring structure, or a bridged ring structure. A divalent heteroatom-containing group may be present between carbons forming the skeleton of the cyclic structure or the chain structure, and some or all of hydrogen atoms on carbon atoms of the cyclic structure or the chain structure may be substituted with another substituent.

As the alicyclic structure, a structure corresponding to the monovalent alicyclic hydrocarbon group having 3 to 20 carbon atoms in R^{1A} and R^{1B} in the formula (1) can be suitably employed.

As the aromatic ring structure, a structure derived from an aromatic ring (an aromatic hydrocarbon ring or a heteroaromatic ring) shown in the iodine-containing aromatic ring structure by replacing an iodine atom is replaced with a hydrogen atom from can be suitably employed.

Examples of the heterocyclic structure include:
oxygen atom-containing alicyclic heterocyclic structures such as oxirane, tetrahydrofuran, tetrahydropyran, dioxolane, and dioxane;
nitrogen atom-containing alicyclic heterocyclic structures such as aziridine, pyrrolidine, piperidine, and piperazine;
sulfur atom-containing alicyclic heterocyclic structures such as thietane, thiolane, and thiane;
alicyclic heterocyclic structures containing a plurality of heteroatoms such as morpholine, 1,2-oxathiolane, and 1,3-oxathiolane;
oxygen atom-containing aromatic heterocyclic structures such as furan and benzofuran;
nitrogen atom-containing aromatic heterocyclic structures such as pyrrole, pyrazole, and triazine;
sulfur atom-containing aromatic heterocyclic structures such as thiophene; and
aromatic heterocyclic structures containing a plurality of heteroatoms such as oxazole, isothiazole, and thiazine.

The heterocyclic structures includes a lactone structure, a cyclic carbonate structure, a sultone structure, a cyclic acetal, and a combination thereof.

As the chain structure, monovalent chain hydrocarbon groups having 1 to 10 carbon atoms represented by R^{1A} and R^{1B} in the above formula (1) can be suitably employed.

Examples of the heteroatom that constitutes the divalent heteroatom-containing group include an oxygen atom, a nitrogen atom, a sulfur atom, a phosphorus atom, a silicon atom, and a halogen atom. Examples of the halogen atom include a fluorine atom, a chlorine atom, a bromine atom, and an iodine atom.

Examples of the divalent heteroatom-containing group include —CO—, —CS—, —NH—, —O—, —S—, and groups obtained by combining them.

As the substituent with which some or all of hydrogen atoms on carbon atoms of the cyclic structure or the chain structure are substituted, a substituent that can be possessed by the divalent linking group represented by L¹ can be suitably employed.

Examples of the onium cation include radiolytic onium cations. Examples of the radiolytic onium cation include a sulfonium cation, a tetrahydrothiophenium cation, and an iodonium cation. Among them, a sulfonium cation or an iodonium cation is preferable.

The onium cation moiety is preferably a fluorine-containing onium cation moiety containing a fluorine atom. The fluorine-containing onium cation moiety preferably has a fluorine-substituted aromatic ring structure. As a result, the radiation absorption efficiency is increased, so that the sensitivity can be improved. The fluorine-substituted aromatic ring structure includes not only a structure in which a fluorine atom is directly bonded to an aromatic ring, but also includes a structure in which a fluorine atom is bonded to an aromatic ring with another structure interposed therebetween.

Thanks to the fact that the structural unit (II) has the above structures in combination, the above functions can be efficiently exhibited.

The radiation-sensitive acid generating resin preferably contains a structural unit represented by the following formula (a1) (hereinafter also referred to as “structural unit (II-1)”), a structural unit represented by the following formula (a2) (hereinafter also referred to as “structural unit (II-2)”), or a structural unit represented by the following formula (a3) (hereinafter also referred to as “structural unit (II-3)”).

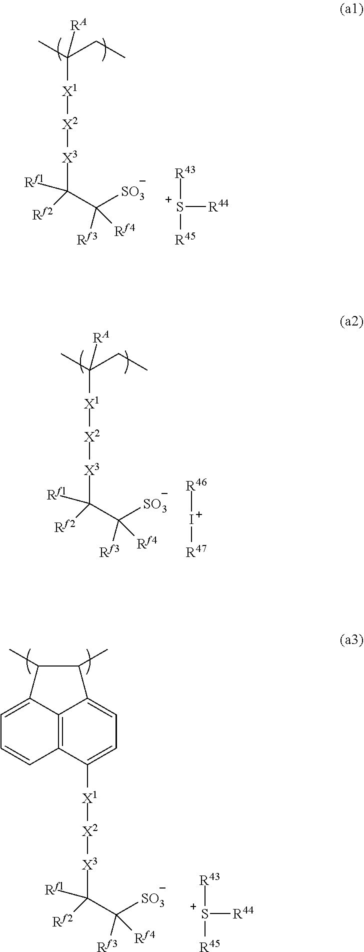

In the formulas, R^{A} is a hydrogen atom or a methyl group. X¹ is a single bond or an ester group. X² is a linear, branched or cyclic alkylene group having 1 to 12 carbon atoms, or an arylene group having 6 to 10 carbon atoms, or a combination thereof, and some of the methylene groups constituting the alkylene group may be replaced by an ether group, an ester group, or a lactone ring-containing group. X³ is a single bond, an ether group, an ester group, a linear or branched alkylene group having 1 to 12 carbon atoms, or a cyclic cycloalkylene group having 3 to 12 carbon atoms, and a part of a methylene group composing the alkylene group may be replaced by an ether group or an ester group. Some or all of the hydrogen atoms of X² and X³ may be replaced by a monovalent hydrocarbon group having 1 to 20 carbon atoms and optionally containing a heteroatom. Rf¹ to Rf⁴ are each independently a hydrogen atom, a fluorine atom, or a trifluoromethyl group, and at least one of Rf¹ to Rf⁴ is a fluorine atom or a fluorinated hydrocarbon group. R⁴³ to R⁴⁷ are each independently a monovalent hydrocarbon group having 1 to 20 carbon atoms and optionally containing a heteroatom, and R⁴³ and R⁴⁴ may be bonded to each other to form a ring together with a sulfur atom to which R⁴³ and R⁴⁴ are bonded. At least one of X² and X³, at least one of R⁴³ through R⁴⁷, or the monovalent hydrocarbon groups having 1 to 20 carbon atoms and optionally containing a heteroatom that replace the hydrogen atoms of X² and X³ may contain an iodine-substituted aromatic ring structure. Preferably, at least one of R⁴³ to R⁴⁵ and at least one of R⁴6 to R⁴⁷ each contain a fluorine-substituted aromatic ring structure.

As the monovalent hydrocarbon group having 1 to 20 carbon atoms in X², X³, and R⁴³ to R⁴⁷, an alkyl group having 1 to 12 carbon atoms, a cycloalkyl group having 3 to 12 carbon atoms, or an aryl group having 6 to 20 carbon atoms is preferable, and some or all of hydrogen atoms of these groups may be substituted with a heteroatom-containing group such as a hydroxy group, a carboxy group, a halogen atom, an oxo group, a cyano group, an amide group, a nitro group, a sultone group, a sulfone group or a sulfonium salt-containing group, an alkoxy group, or an alkoxycarbonyl group, and a part of a methylene group composing these groups may be substituted with an ether group, an ester group, a carbonyl group, a carbonate group, or a sulfonate ester group.

Preferably, the structural unit (II-1) and the structural unit (II-2) are each represented by the following formulas (a1-1), (a2-1), and (a3-1).

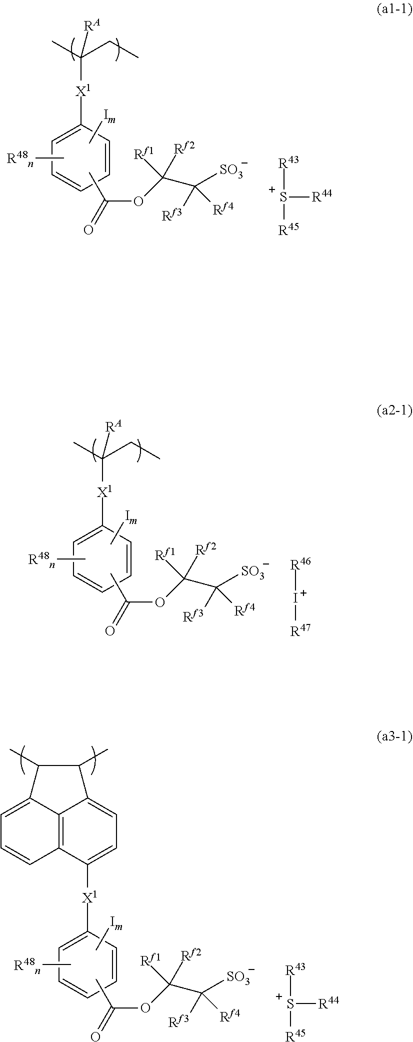

In the formulas, R^{A}, R³ to R⁷, Rf¹ to Rf⁴, and X¹ have the same meanings as in the formula (a1) or (a2). R⁴⁸ is a linear, branched or cyclic alkyl group having 1 to 4 carbon atoms, a halogen atom other than iodine, a hydroxy group, a linear, branched or cyclic alkoxy group having 1 to 4 carbon atoms, or a linear, branched or cyclic alkoxycarbonyl group having 2 to 5 carbon atoms. m is an integer of 0 to 4. n is an integer of 0 to 3.

Examples of the organic acid anion moieties of the monomers that afford the structural unit (II-1), the structural unit (II-2), and the structural unit (II-3) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or another substituent.

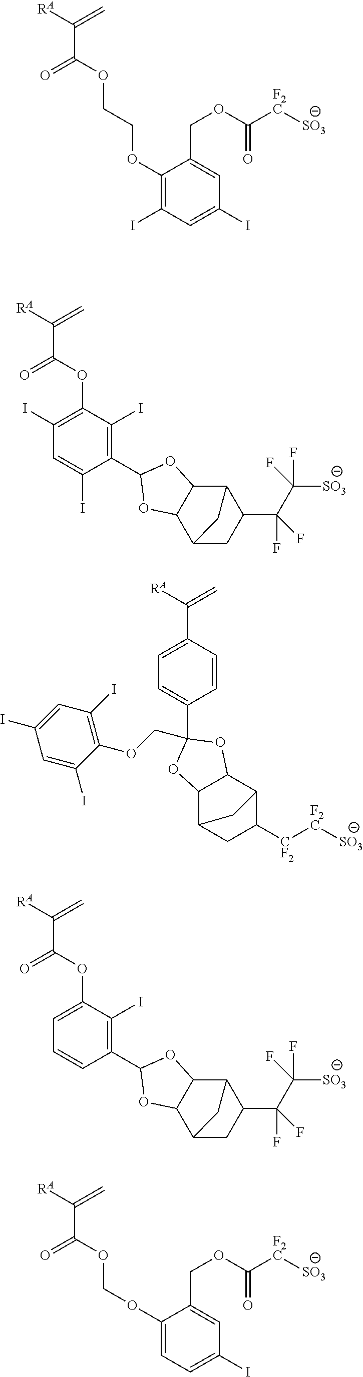

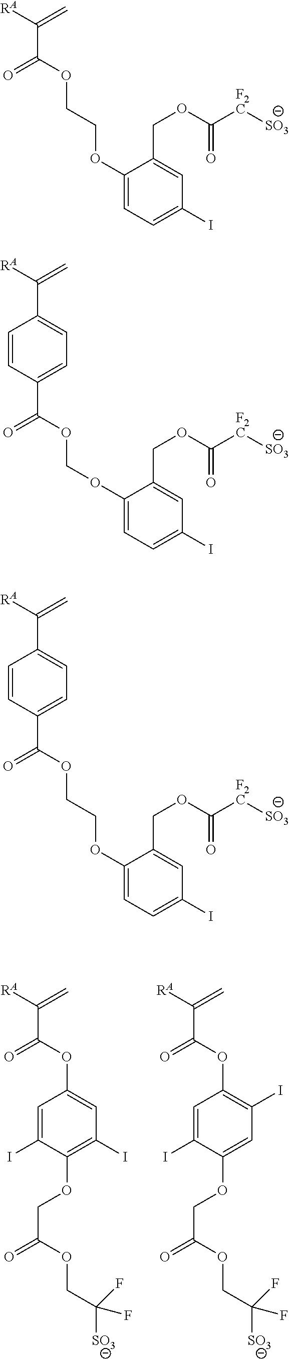

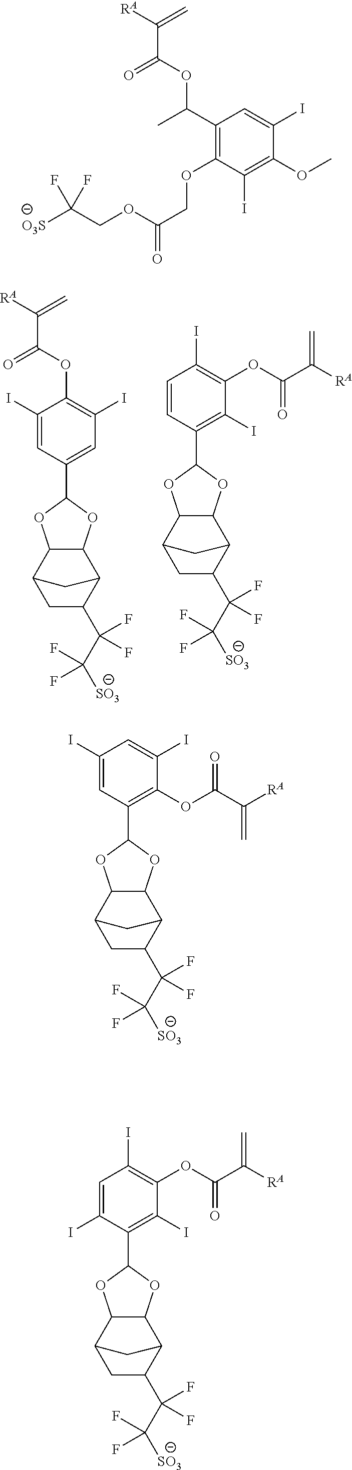

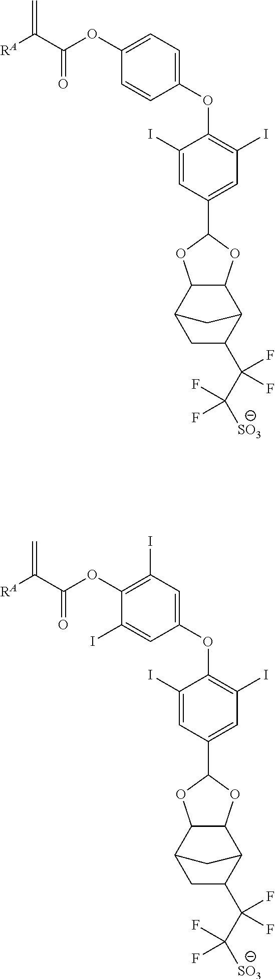

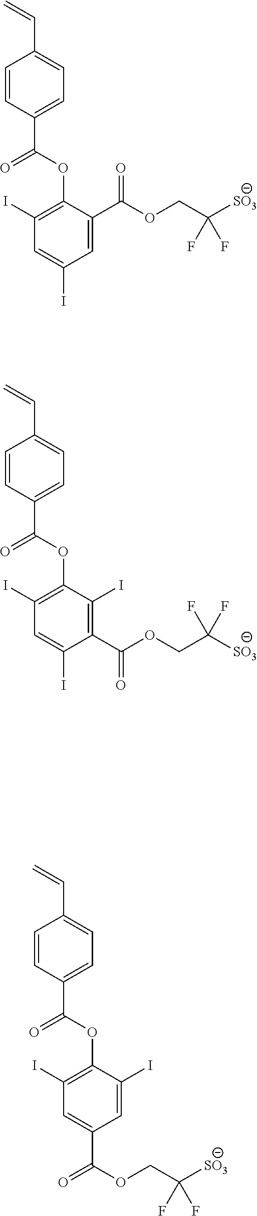

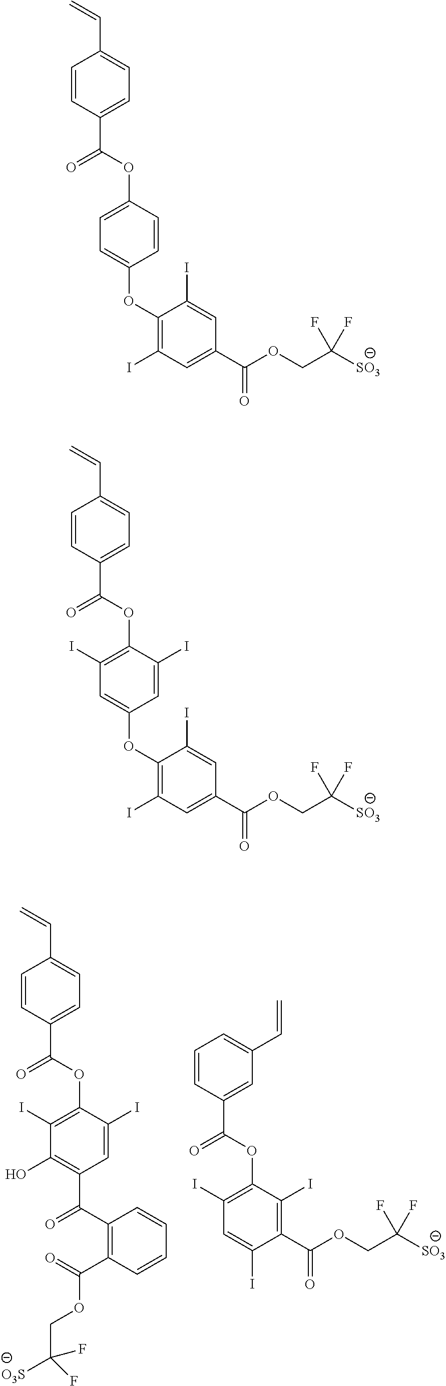

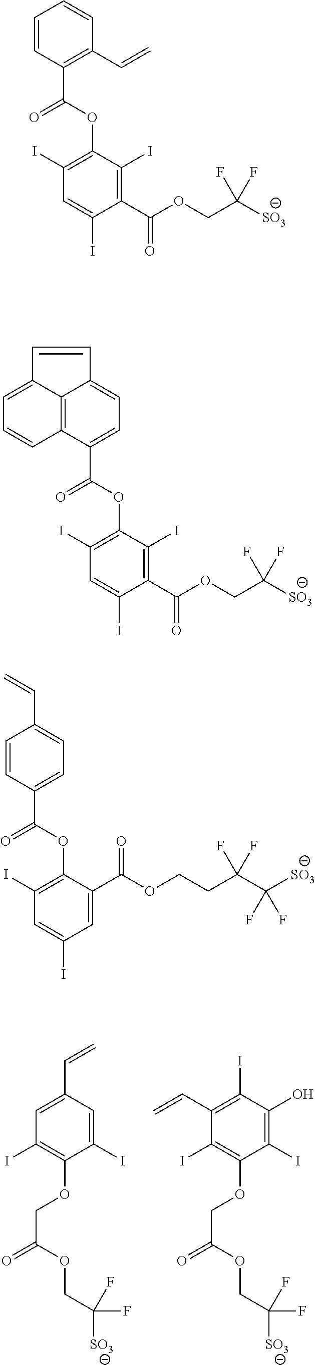

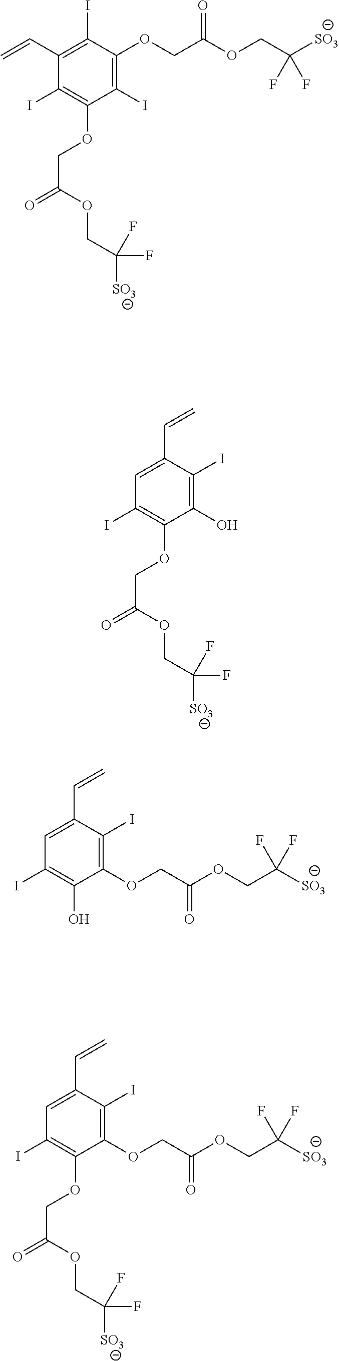

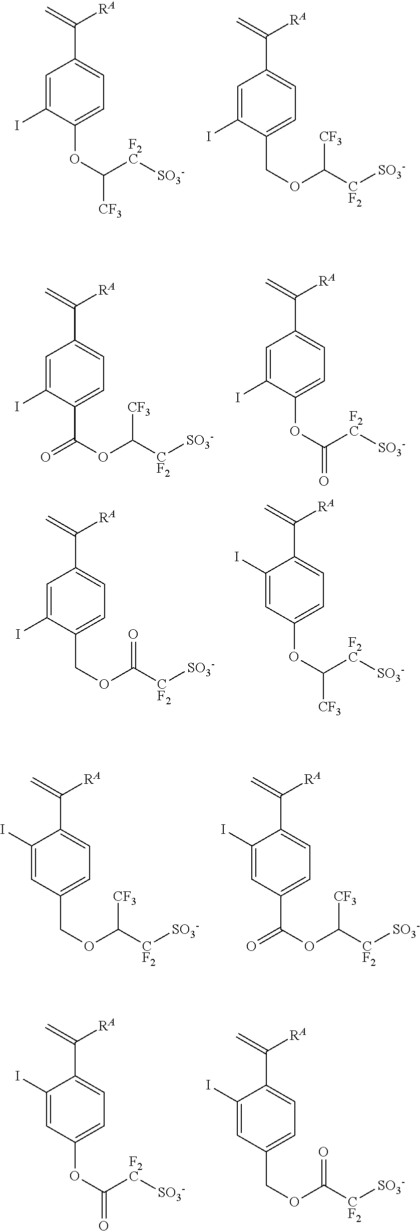

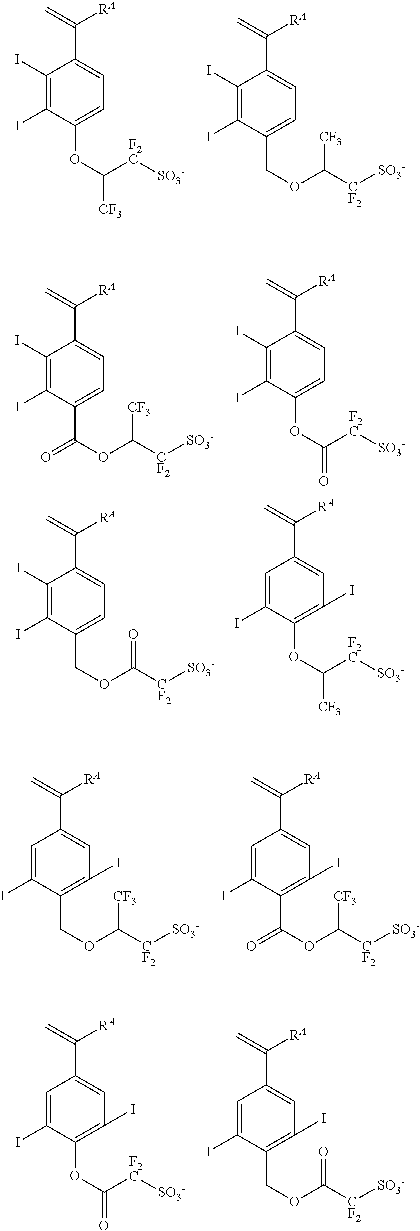

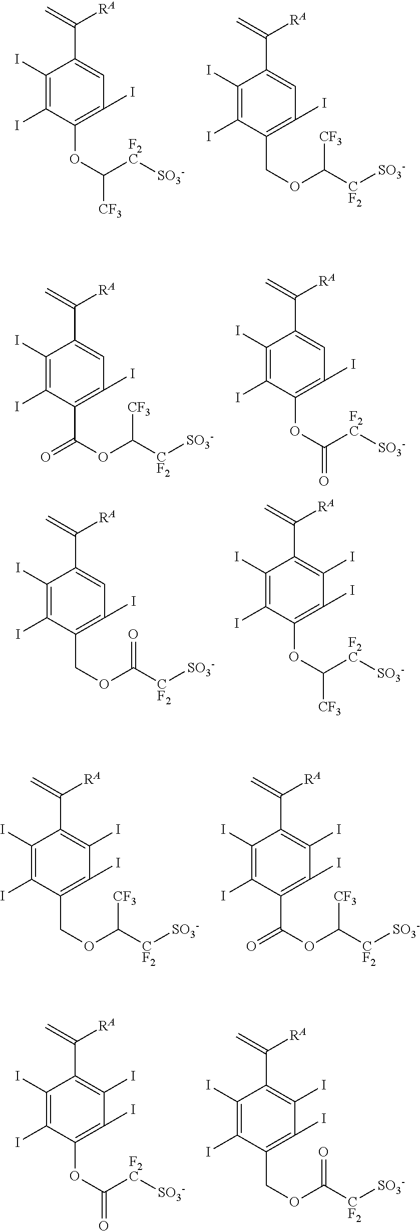

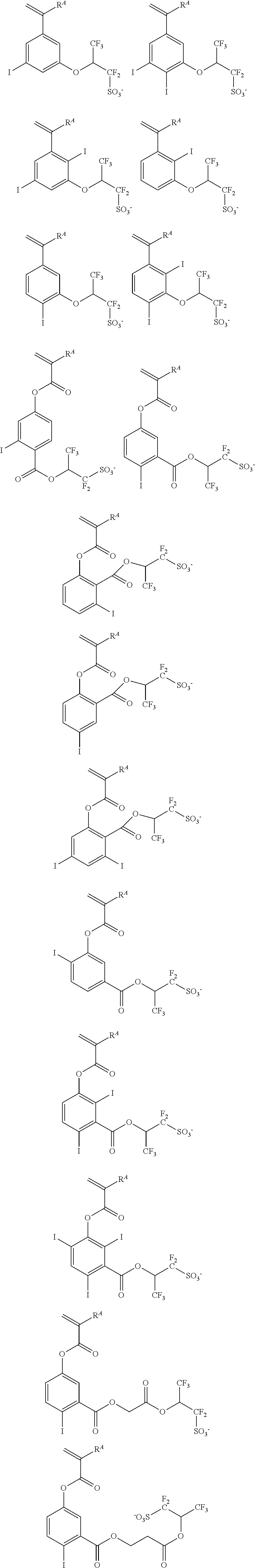

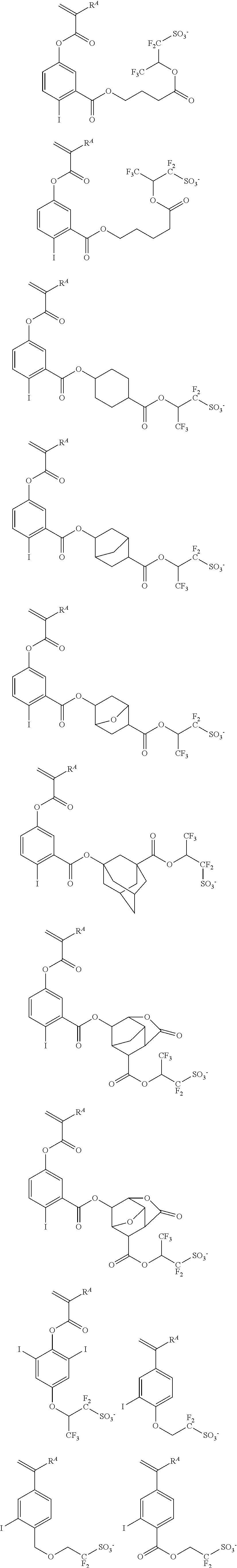

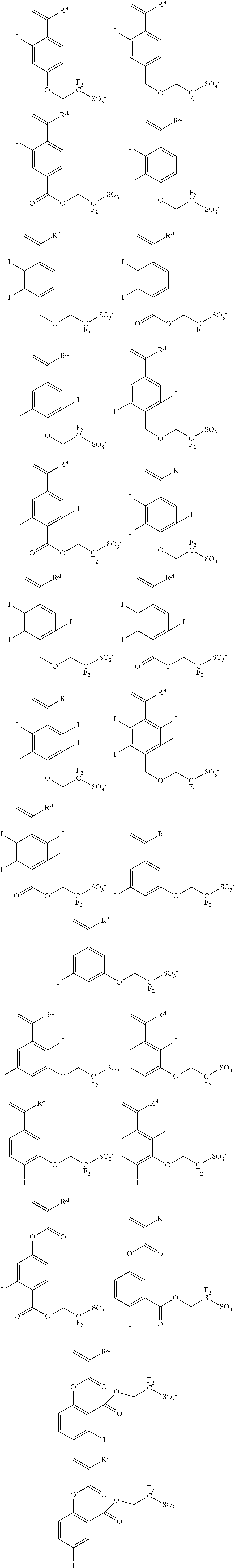

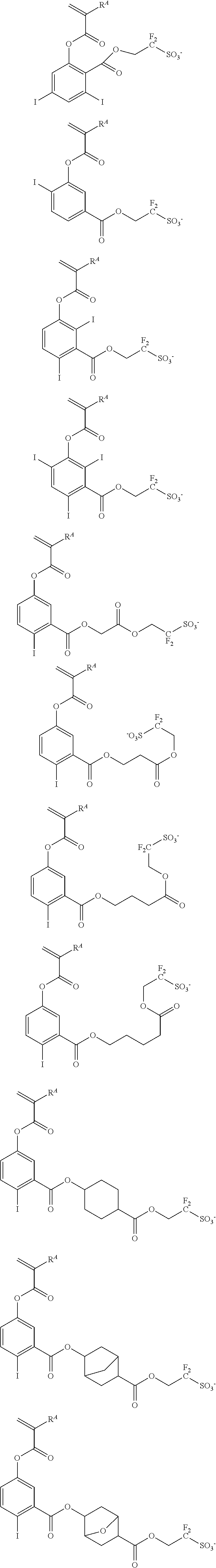

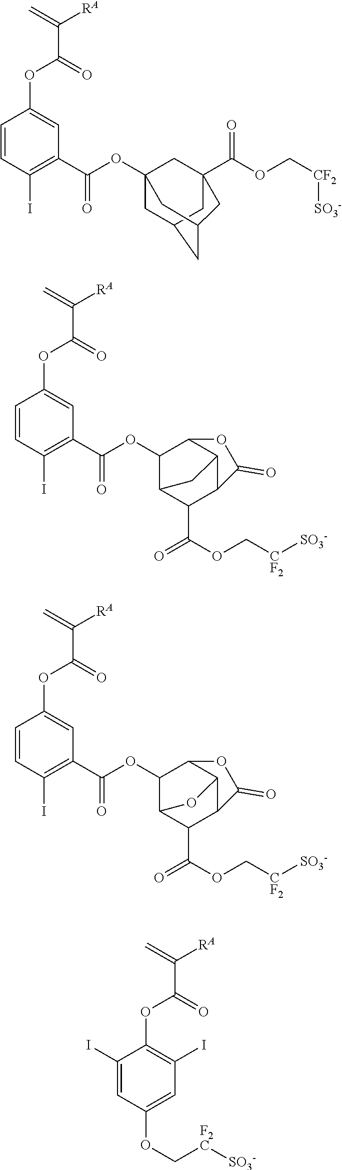

The onium cation moieties of the structural unit (II-1) and the structural unit (II-3) are preferably represented by the following formula (Q-1).

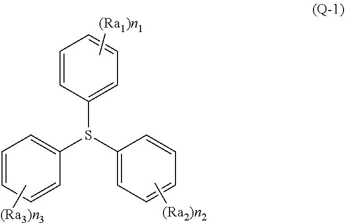

In the formula (Q-1), Ra1 and Ra2 each independently represent a substituent. n1 represents an integer of 0 to 5, and when n1 is 2 or more, the plurality of Ra1s may be the same as or different from each other. n2 represents an integer of 0 to 5, and when n2 is 2 or more, the plurality of Ra2s may be the same as or different from each other. n3 represents an integer of 0 to 5, and when n3 is 2 or more, the plurality of Ra3s may be the same as or different from each other. Ra3 represents a fluorine atom or a group having one or more fluorine atoms. Ra1 and Ra2 may be linked to each other to form a ring. When n1 is 2 or more, the plurality of Ra1s may be linked to each other to form a ring. When n2 is 2 or more, the plurality of Ra2s may be linked to each other to form a ring.

The substituent represented by Ra1 and Ra2 is preferably an alkyl group, a cycloalkyl group, an alkoxy group, a cycloalkyloxy group, an alkoxycarbonyl group, an alkylsulfonyl group, a hydroxy group, a halogen atom, or a halogenated hydrocarbon group.

The alkyl group as Ra1 and Ra2 may be either a linear alkyl group or a branched alkyl group. The alkyl group is preferably one having 1 to 10 carbon atoms, and examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, and an n-decyl group. Among them, a methyl group, an ethyl group, an n-butyl group, and a t-butyl group are particularly preferable.

Examples of the cycloalkyl group as Ra1 and Ra2 include monocyclic or polycyclic cycloalkyl groups (preferably cycloalkyl groups having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among them, a cyclopropyl group, a cyclopentyl group, a cyclohexyl group, a cyclohexyl group, a cycloheptyl group, and a cyclooctyl group are particularly preferable.

Examples of the alkyl group moiety of the alkoxy group as Ra1 and Ra2 include those listed above as the alkyl group as Ra1 and Ra2. As the alkoxy group, a methoxy group, an ethoxy group, an n-propoxy group, and an n-butoxy group are particularly preferable.

Examples of the cycloalkyl group moiety of the cycloalkyloxy group as Ra1 and Ra2 include those listed above as the cycloalkyl group as Ra1 and Ra2. As the cycloalkyloxy group, a cyclopentyloxy group and a cyclohexyloxy group are particularly preferable.

Examples of the alkoxy group moiety of the alkoxycarbonyl group as Ra1 and Ra2 include those listed above as the alkoxy group as Ra1 and Ra2. As the alkoxycarbonyl group, a methoxycarbonyl group, an ethoxycarbonyl group, and an n-butoxycarbonyl group are particularly preferable.

Examples of the alkyl group moiety of the alkylsulfonyl group as Ra1 and Ra2 include those listed above as the alkyl group as Ra1 and Ra2. Examples of the cycloalkyl group moiety of the cycloalkylsulfonyl group as Ra1 and Ra2 include those listed above as the cycloalkyl group as Ra1 and Ra2. As the alkylsulfonyl group or the cycloalkylsulfonyl group, a methanesulfonyl group, an ethanesulfonyl group, an n-propanesulfonyl group, an n-butanesulfonyl group, a cyclopentanesulfonyl group, and a cyclohexanesulfonyl group are particularly preferable.

Each of the groups Ra1 and Ra2 may further have a substituent. Examples of the substituent include a halogen atom such as a fluorine atom (preferably a fluorine atom), a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

Examples of the halogen atom as Ra1 and Ra2 include a fluorine atom, a chlorine atom, a bromine atom, and an iodine atom, and a fluorine atom and an iodine atom are preferable.

As the halogenated hydrocarbon group as Ra1 and Ra2, a halogenated alkyl group is preferable. Examples of the alkyl group and the halogen atom composing the halogenated alkyl group include those described above. Among them, a fluorinated alkyl group is preferable, and CF₃ is more preferable.

As described above, Ra1 and Ra2 may be linked to each other to form a ring (namely, a heterocyclic ring containing a sulfur atom). In this case, it is preferable that Ra1 and Ra2 be bonded to each other to form a single bond or a divalent linking group. Examples of the divalent linking group include —COO—, —OCO—, —CO—, —O—, —S—, —SO—, —SO₂—, an alkylene group, a cycloalkylene group, an alkenylene group, and combinations of two or more thereof, and those having 20 or less carbon atoms in total are preferable. When Ra1 and Ra2 are linked to each other to form a ring, it is preferable that Ra1 and Ra2 be bonded to each other to form —COO—, —OCO—, —CO—, —O—, —S—, —SO—, —SO₂—, or a single bond. Among them, it is more preferable to form —O—, —S—, or a single bond, and it is particularly preferable to form a single bond. When n1 is 2 or more, the plurality of Ra1s may be linked to each other to form a ring, and when n2 is 2 or more, the plurality of Ra2s may be linked to each other to form a ring. Examples thereof include an aspect in which two Ra1s are linked to each other to form a naphthalene ring together with a benzene ring to which two Ra1s are bonded.

Ra3 is a fluorine atom, or a group having one or more fluorine atoms. Examples of the group having a fluorine atom may include groups in which a halogen atom of the alkyl group, cycloalkyl group, alkoxy group, cycloalkyloxy group, alkoxycarbonyl group, and alkylsulfonyl group as Ra1 and Ra2 is substituted with a fluorine atom. Among them, fluorinated alkyl groups are suitable, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉ are more suitable, and CF₃ is particularly suitable.

Ra3 is preferably a fluorine atom, or CF₃, more preferably a fluorine atom.

n1 and n2 are each independently preferably an integer of 0 to 3, preferably an integer of 0 to 2.

n3 is preferably an integer of 1 to 3, more preferably 1 or 2.

(n1+n2+n3) is preferably an integer of 1 to 15, more preferably an integer of 1 to 9, still more preferably an integer of 2 to 6, particularly preferably an integer of 3 to 6. When (n1+n2+n3) is 1, it is preferable that n3=1, and Ra3 be a fluorine atom, or CF₃. When (n1+n2+n3) is 2, a combination in which n1=n3=1, and Ra1 and Ra3 are each independently a fluorine atom, or CF₃, and a combination in which n3=2, and Ra3 is a fluorine atom, or CF₃ are preferable. When (n1+n2+n3) is 3, a combination in which n1=n2=n3=1, and Ra1 to Ra3 are each independently a fluorine atom, or CF₃ is preferable. When (n1+n2+n3) is 4, a combination in which n1=n3=2, and Ra1 and Ra3 are each independently a fluorine atom, or CF₃ is preferable. When (n1+n2+n3) is 5, a combination in which n1=n2=1 and n3=3, and Ra1 to Ra3 are each independently a fluorine atom, or CF₃, a combination in which n1=n2=2 and n3=1, and Ra1 to Ra3 are each independently a fluorine atom, or CF₃, and a combination in which n3=5, and Ra3s are each independently a fluorine atom, or CF₃ are preferable. When (n1+n2+n3) is 6, a combination in which n1=n2=n3=2, and Ra1 to Ra3 are each independently a fluorine atom, or CF₃ is preferable.

Specific examples of such an onium cation moiety represented by the formula (Q-1) include the following. In the sulfonium cation moiety having a fluorine-substituted aromatic ring structure shown below, a structure in which a fluorine atom or a group having one or more fluorine atoms is replaced by a hydrogen atom or another substituent containing no fluorine atom can also be suitably employed.

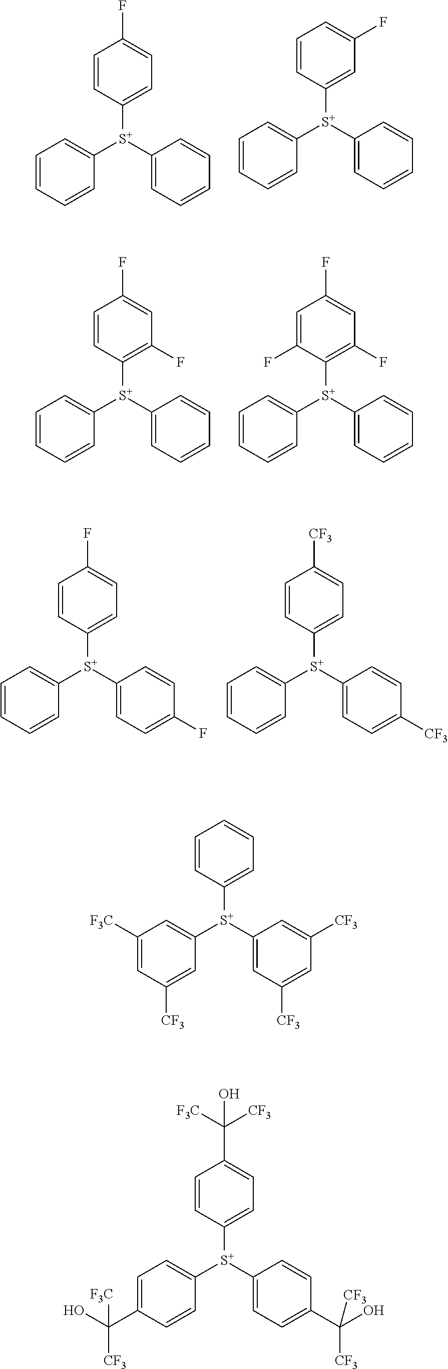

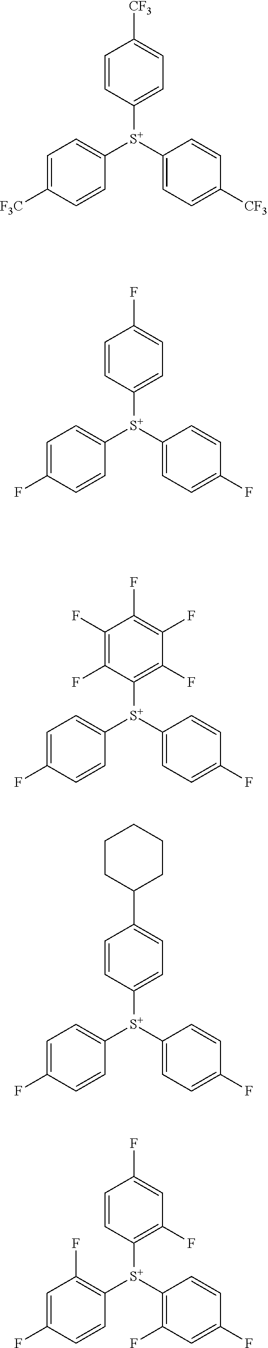 [SMILES: FC(F)(F)c1ccc([S+](c2ccc(C(F)(F)F)cc2)c2ccc(C(F)(F)F)cc2)cc1 ; Fc1ccc([S+](c2ccc(F)cc2)c2ccc(F)cc2)cc1 ; Fc1ccc([S+](c2ccc(F)cc2)c2c(F)c(F)c(F)c(F)c2F)cc1 ; Fc1ccc([S+](c2ccc(F)cc2)c2ccc(C3CCCCC3)cc2)cc1 ; Fc1ccc([S+](c2ccc(F)cc2F)c2ccc(F)cc2F)c(F)c1]

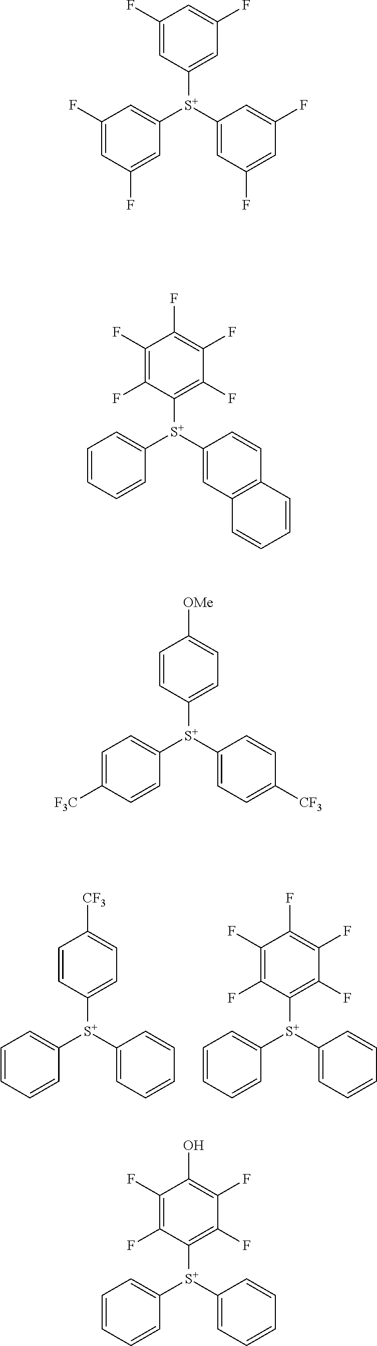 [SMILES: Fc1cc(F)cc([S+](c2cc(F)cc(F)c2)c2cc(F)cc(F)c2)c1 ; Fc1c(F)c(F)c([S+](c2ccccc2)c2ccc3ccccc3c2)c(F)c1F ; COc1ccc([S+](c2ccc(C(F)(F)F)cc2)c2ccc(C(F)(F)F)cc2)cc1 ; FC(F)(F)c1ccc([S+](c2ccccc2)c2ccccc2)cc1 ; Fc1c(F)c(F)c([S+](c2ccccc2)c2ccccc2)c(F)c1F ; Oc1c(F)c(F)c([S+](c2ccccc2)c2ccccc2)c(F)c1F]

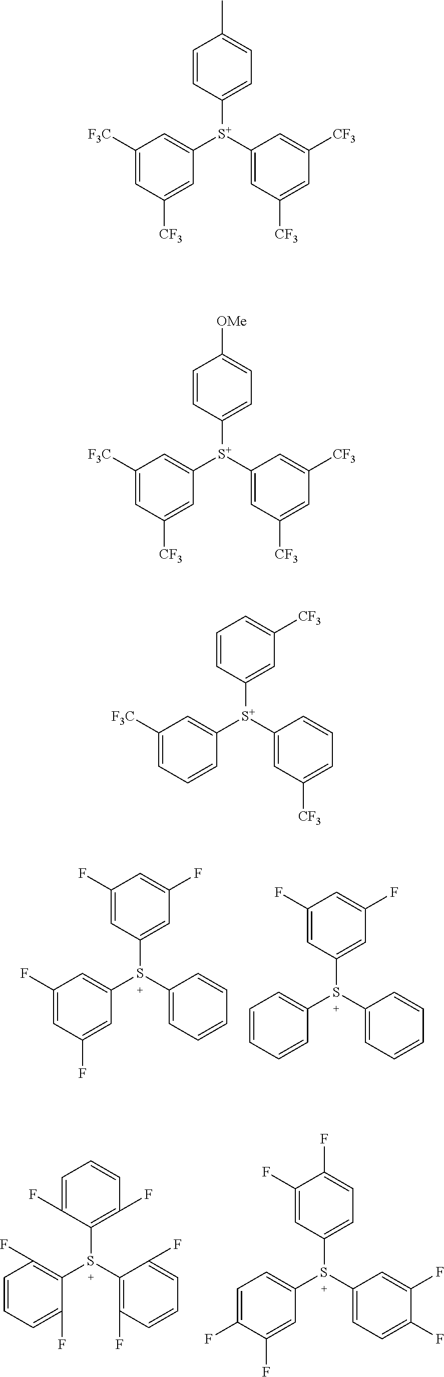

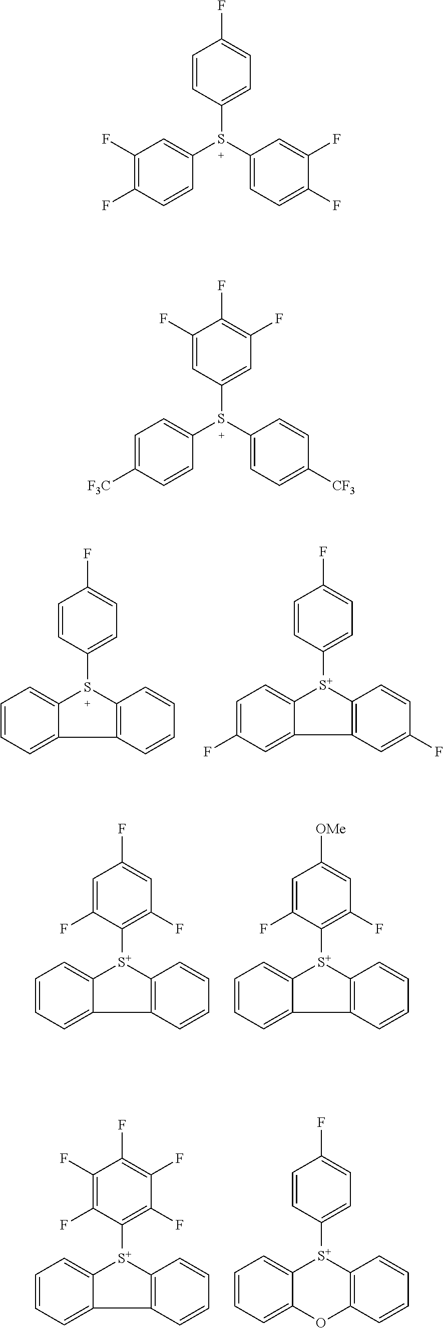

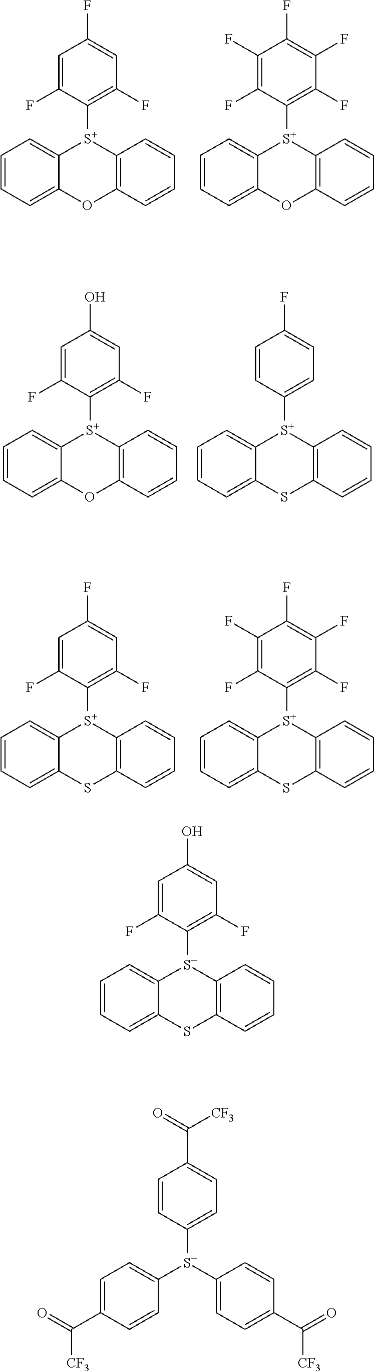

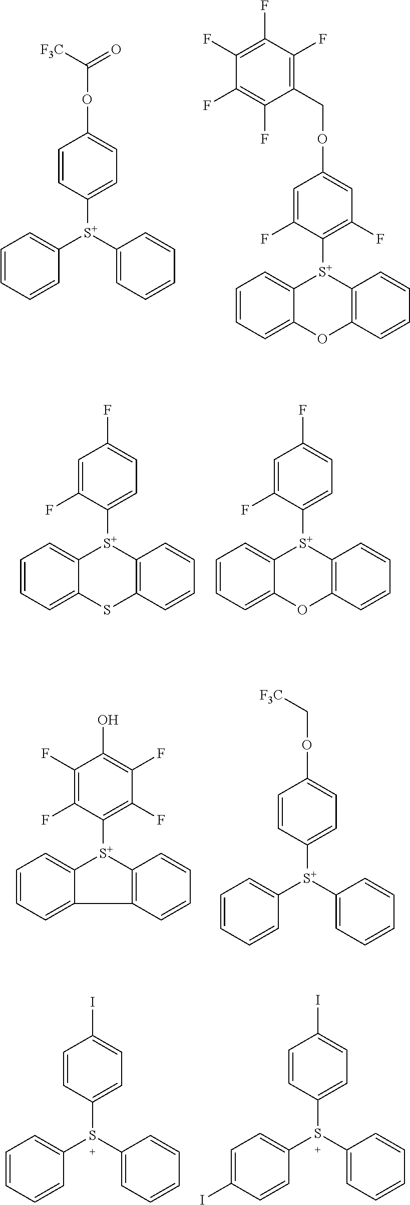

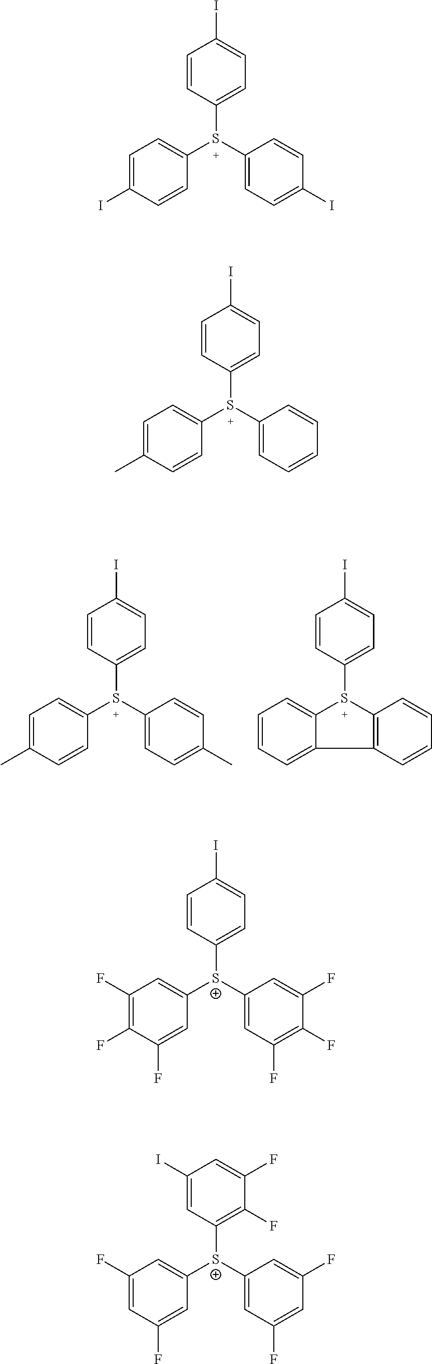

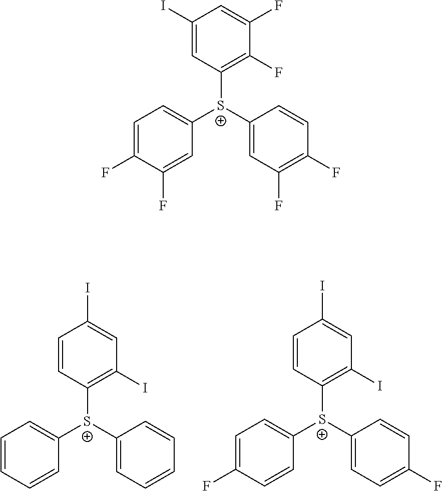 [SMILES: Fc1ccc([S+](c2ccc(F)c(F)c2)c2cc(I)cc(F)c2F)cc1F ; Ic1ccc([S+](c2ccccc2)c2ccccc2)c(I)c1 ; Fc1ccc([S+](c2ccc(F)cc2)c2ccc(I)cc2I)cc1]

When the onium cation moiety of the structural unit a2 contains a fluorine-substituted aromatic ring structure, the onium cation moiety is preferably a diaryliodonium cation having one or more fluorine atoms.

The lower limit of the content of the structural unit (II-1) through the structural unit (II-3) (when a plurality of types is contained, the total content thereof is taken) is preferably 1 mol %, more preferably 5 mol %, and still more preferably 8 mol % based on all structural units composing the radiation-sensitive acid generating resin. The upper limit of the content is preferably 30 mol %, more preferably 20 mol %, and still more preferably 15 mol %. When the contents of the structural unit (II-1) to the structural unit (II-3) are adjusted to within the above range, a function as an acid generator can be sufficiently exhibited.

The monomer that affords the structural units (II-1) to (II-3) can be synthesized, for example, by the same method as that for a sulfonium salt having a polymerizable anion described in JP-B-5201363.

### (Structural Unit (III))

The radiation-sensitive acid generating resin may contain another structural unit (III) having an acid-dissociable group together with the structural unit (I). The acid-dissociable group of the structural unit (III) contains no iodine-substituted aromatic ring structure. Another structural unit having an acid-dissociable group is preferably a structural unit represented by the following formula (b1) (hereinafter also referred to as structural unit (III-1)) or a structural unit represented by the following formula (b2) (hereinafter also referred to as structural unit (III-2)), both excluding structures corresponding to the structural unit (I).

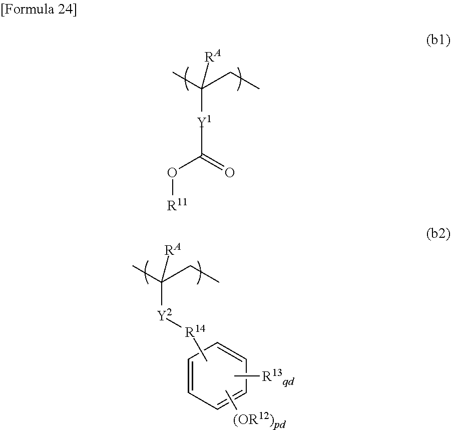

In the above formulas, R^{A} has the same meaning as in the above formulas (a1) and (a2). Y¹ is a single bond, a phenylene group, or a naphthylene group, or a linking group having 1 to 12 carbon atoms containing an ester group. Y² is a single bond or an ester group. R¹¹ and R¹² are each independently an acid-dissociable group. R¹³ is a halogen atom other than an iodine atom, a trifluoromethyl group, a cyano group, an alkyl or alkoxy group having 1 to 6 carbon atoms, or an acyl, acyloxy, or alkoxycarbonyl group having 2 to 7 carbon atoms. R¹⁴ is a single bond or an alkylene group having 1 to 6 carbon atoms, and some of the carbon atoms may be replaced by an ether group or an ester group. pd is 1 or 2. qd is an integer of 0 to 4.

Examples of the structural unit (III-1) include, but are not limited to, those shown below. In the following formulas, R^{A} and R¹¹ are the same as described above.

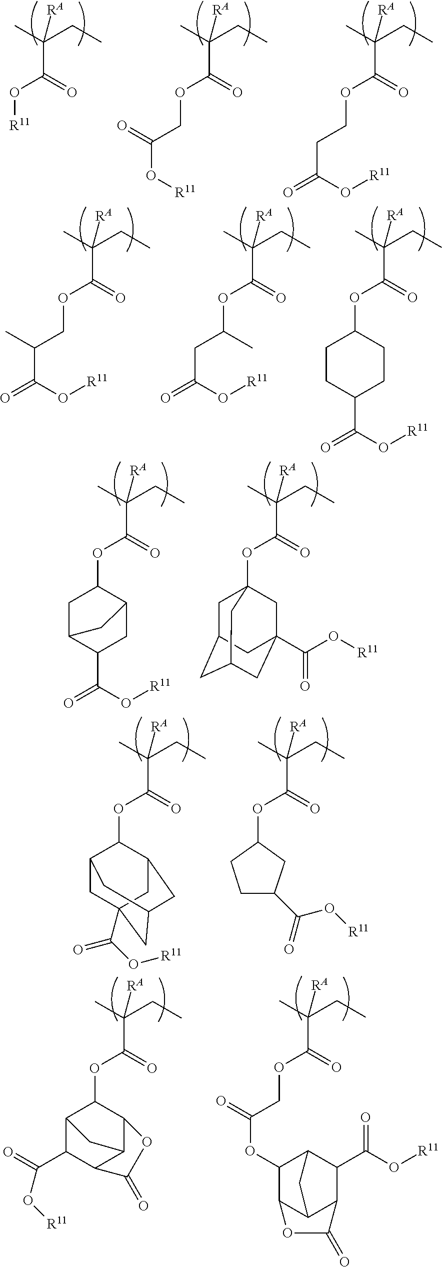

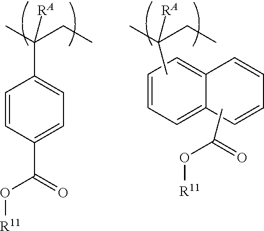

Examples of the structural unit (III-2) include, but are not limited to, those shown below. In the following formulas, R^{A} and R¹² are the same as described above.

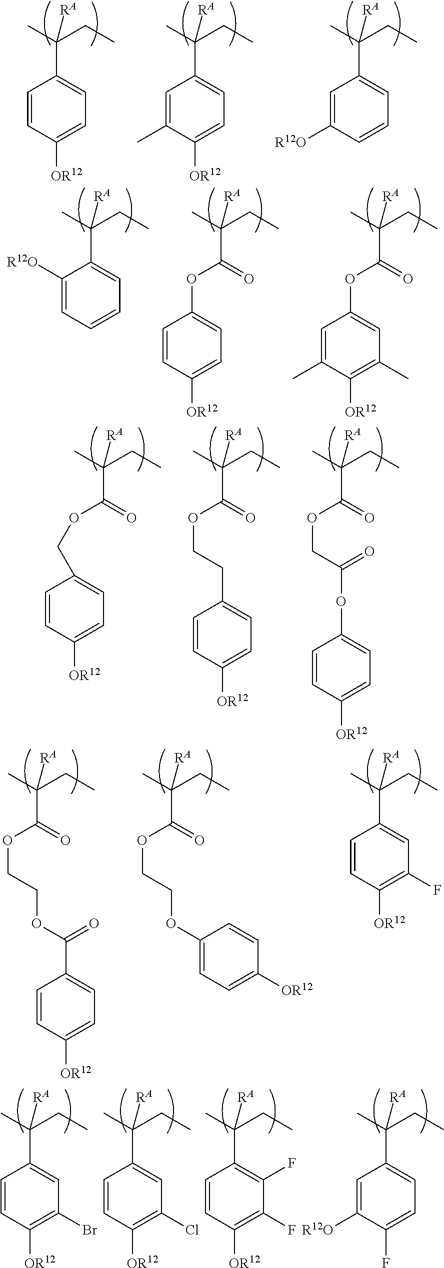

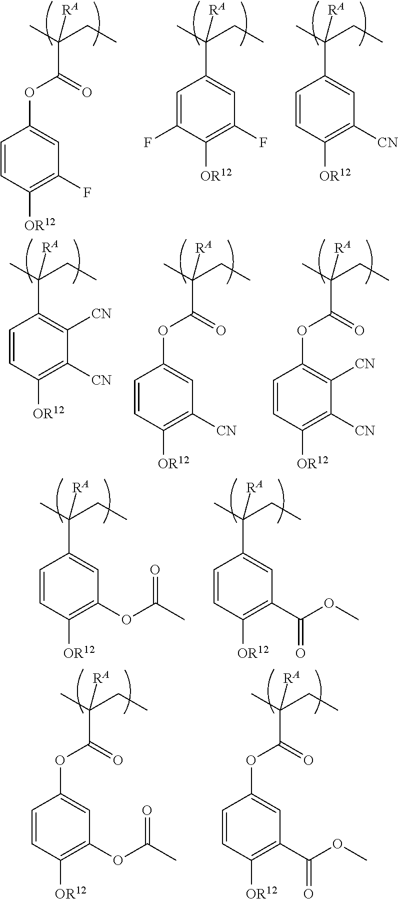

Examples of the acid-dissociable group represented by R¹¹ and R¹² in the formulas (b1) and (b2) include those described in JP-A-2013-80033 and JP-A-2013-83821.

Typically, examples of the acid-dissociable group include those represented by the following formulas (AL-1) to (AL-3).

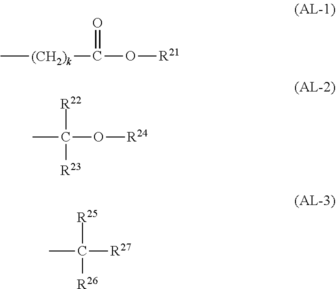

In the formulas (AL-1) and (AL-2), R²¹ and R²⁴ are a monovalent hydrocarbon group having 1 to 40, preferably 1 to 20 carbon atoms such as a branched or cyclic alkyl group, and may contain a heteroatom such as an oxygen atom, a sulfur atom, a nitrogen atom, or a fluorine atom. R²² and R²³ are each independently a hydrogen atom or a monovalent hydrocarbon group having 1 to 20 carbon atoms such as a linear, branched or cyclic alkyl group, and may contain a heteroatom such as an oxygen atom, a sulfur atom, a nitrogen atom, or a fluorine atom. Any two of R²², R²³, and R²⁴ may be bonded to each other to form a ring, especially, alicyclic ring, having 3 to 20 carbon atoms, preferably 4 to 16 carbon atoms, together with the carbon atom or the carbon atom and the oxygen atom to which they are bonded. k is an integer of 1 to 5.

In the formula (AL-3), R²⁵, R²⁶ and R²⁷ are each independently a monovalent hydrocarbon group having 1 to 20 carbon atoms such as a linear, branched or cyclic alkyl group, and may contain a heteroatom other than an iodine atom such as an oxygen atom, a sulfur atom, a nitrogen atom or a fluorine atom. Any two of R²⁵, R²⁶ and R²⁷ may be bonded to each other to form a ring, especially, alicyclic ring, having 3 to 20 carbon atoms, preferably 4 to 16 carbon atoms, together with the carbon atom to which they are bonded.

The lower limit of the content of the structural unit (III-1) or the structural unit (III-2) (when a plurality of types is contained, the total content thereof is taken) is preferably 10 mol %, more preferably 15 mol %, still more preferably 20 mol %, and particularly preferably 25 mol % based on all structural units composing the base resin. The upper limit of the content is preferably 70 mol %, more preferably 60 mol %, still more preferably 55 mol %, and particularly preferably 50 mol %. When the content of the structural unit (III-1) or the structural unit (III-2) is adjusted to within the above range, the patternability of the radiation-sensitive resin composition can be further improved.

### (Structural Unit (IV))

Preferably, the radiation-sensitive acid generating resin further contains a structural unit (IV) having a phenolic hydroxy group. Examples of the monomer that affords the structural unit (IV) include, but are not limited to, those shown below. In the following formulas, R^{A} is the same as described above.

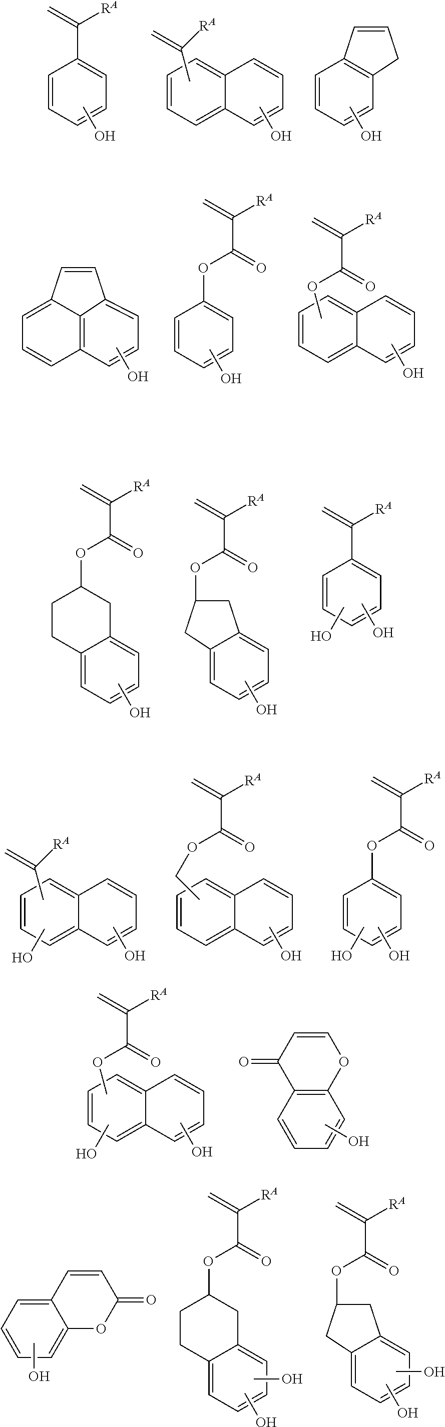

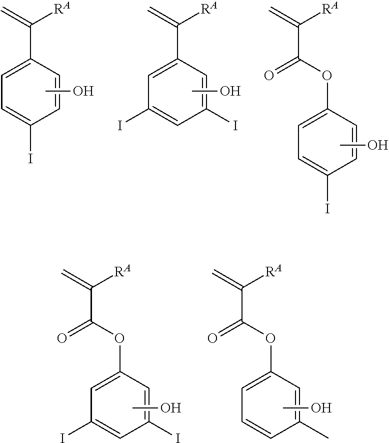

The lower limit of the content of the structural unit (IV) (when a plurality of types is contained, the total content thereof is taken) is preferably 15 mol %, more preferably 20 mol %, still more preferably 25 mol %, and particularly preferably 30 mol % based on all structural units composing the radiation-sensitive acid generating resin. The upper limit of the content is preferably 70 mol %, more preferably 60 mol %, still more preferably 55 mol %, and particularly preferably 50 mol %. When the content of the structural unit (IV) is adjusted to within the above range, the patternability of the radiation-sensitive resin composition can be further improved.

### (Structural Unit (V))

The radiation-sensitive acid generating resin may further contain another structural unit (V) containing an alcoholic hydroxy group, a carboxy group, a lactone ring, a sultone ring, an ether group, an ester group, a carbonyl group, or a cyano group as an adhesive group. Examples of the monomer that affords the other structural unit (V) include, but are not limited to, those shown below. In the following formulas, R^{A} is the same as described above.

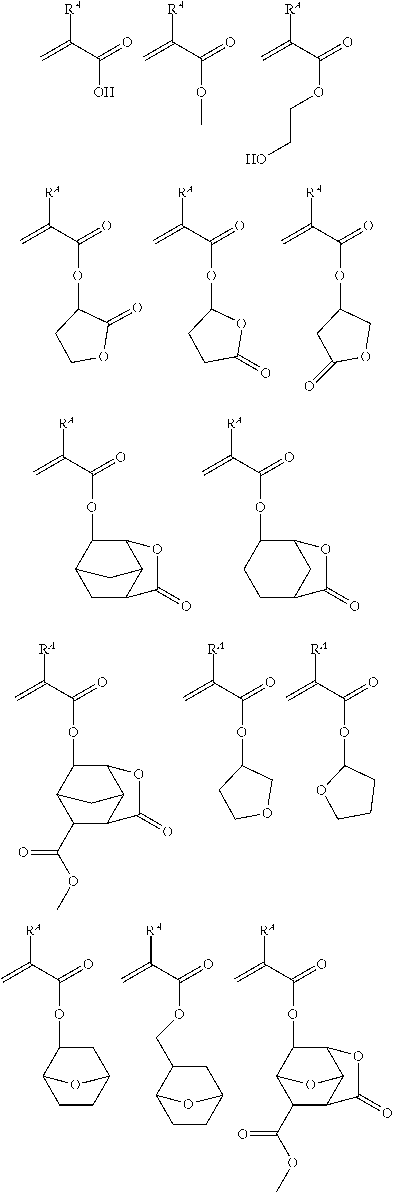

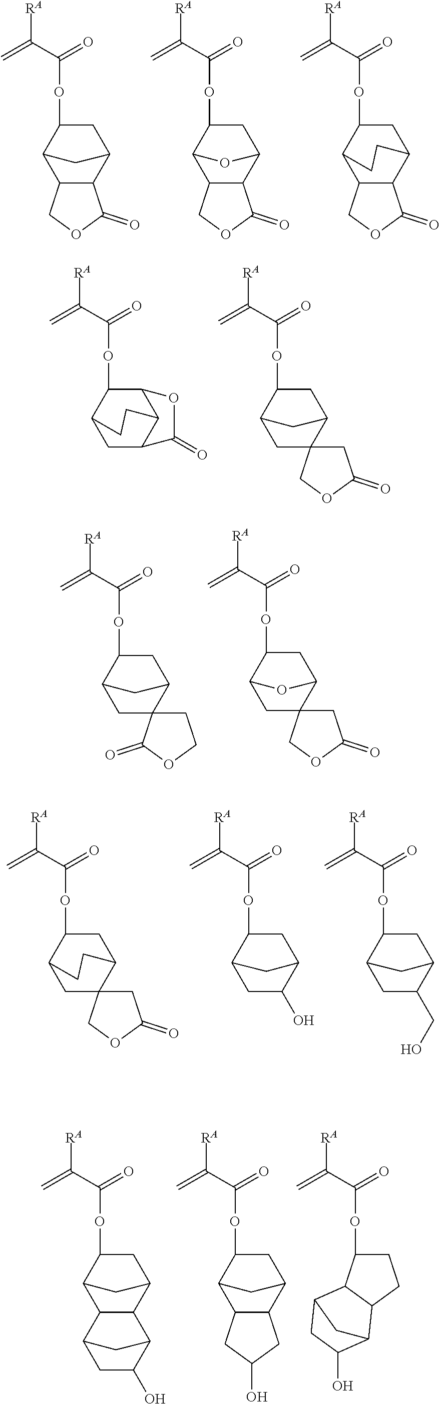

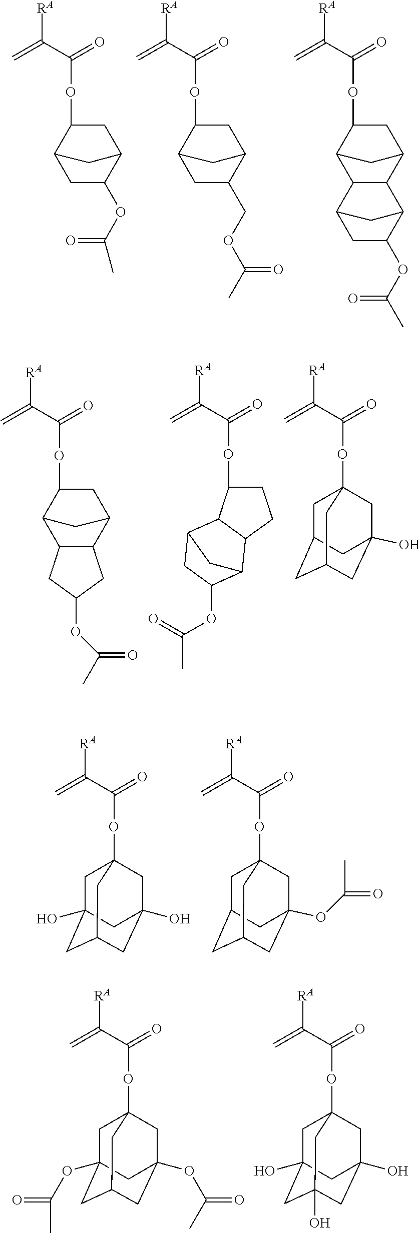

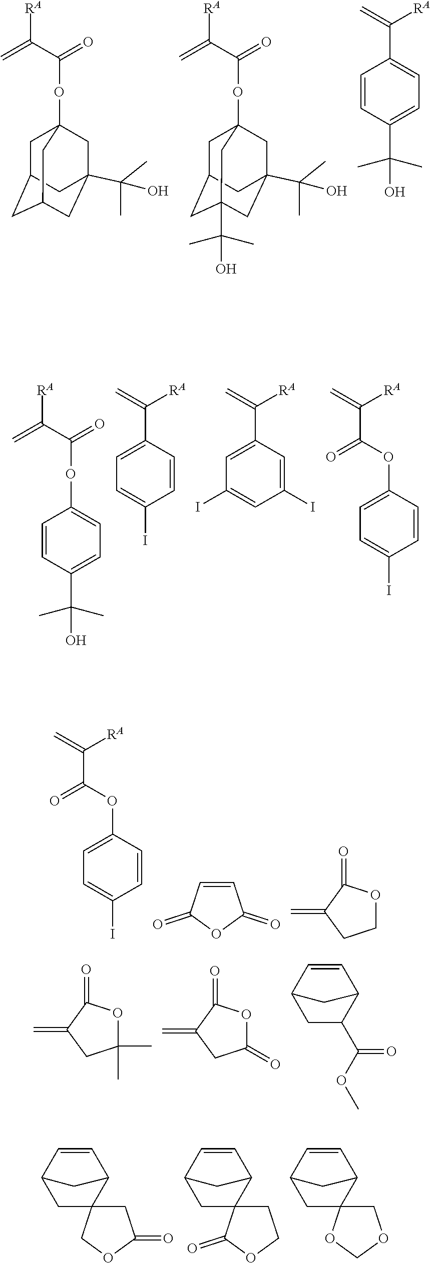

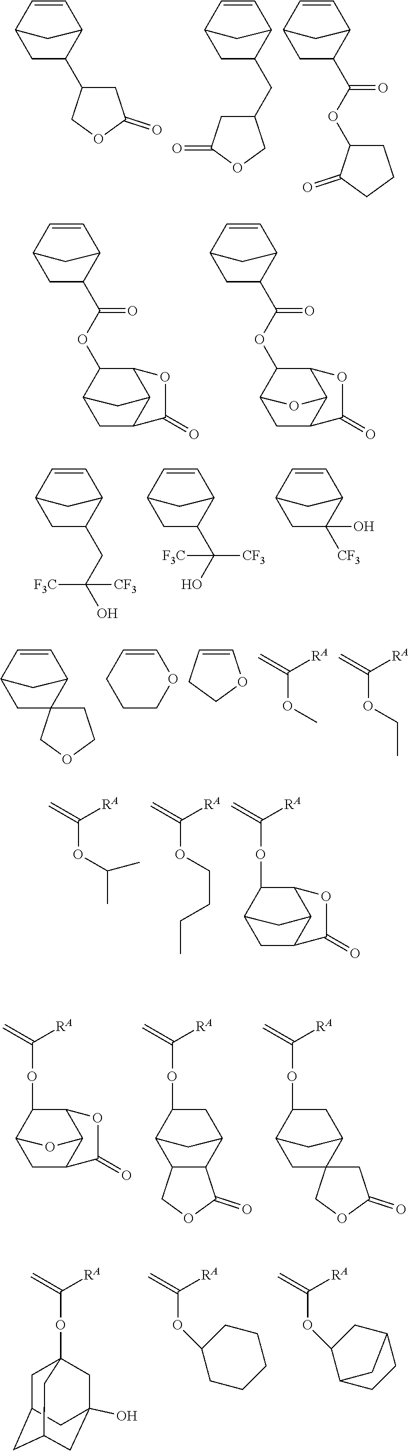

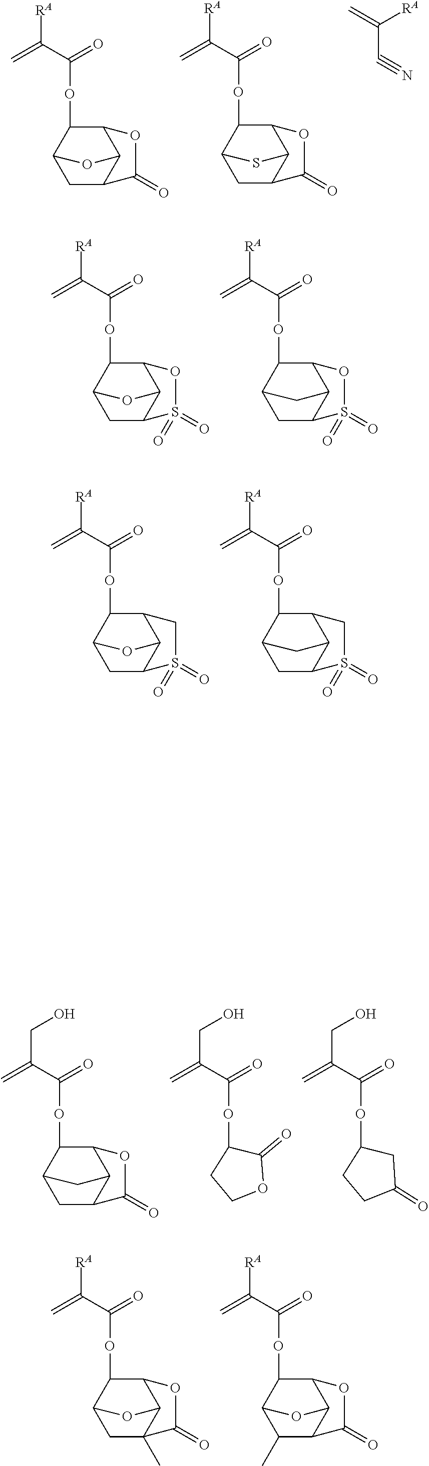

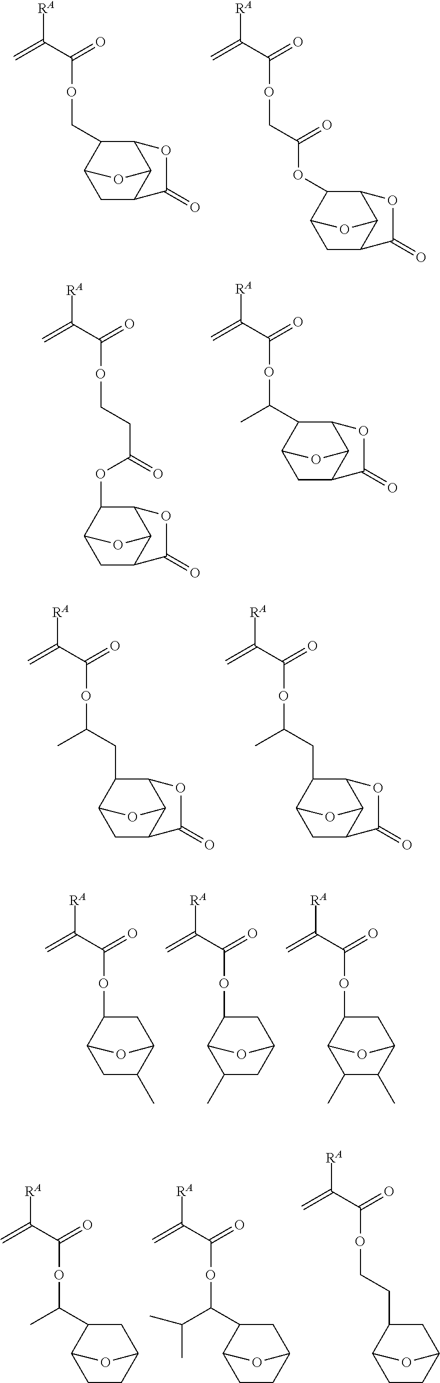

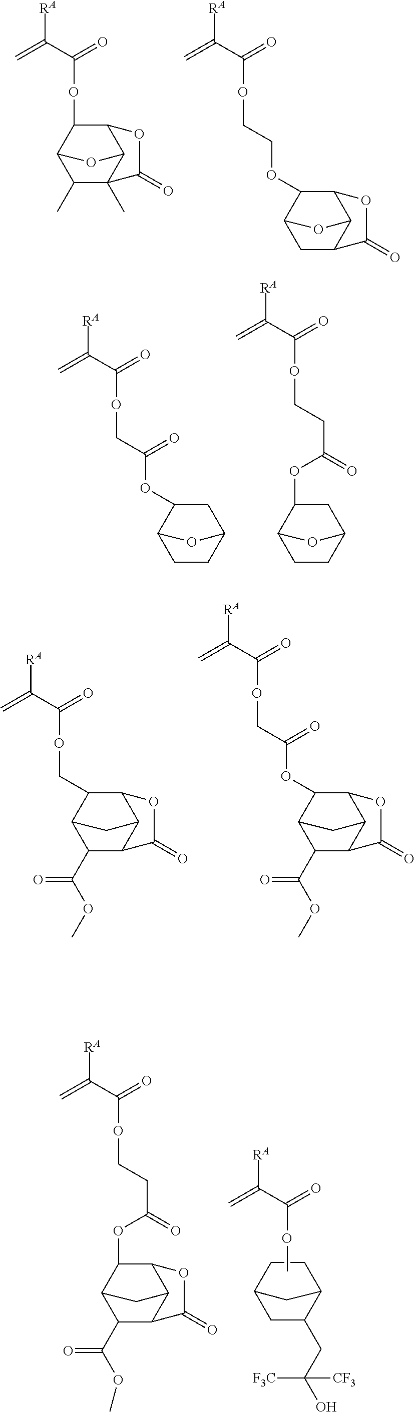

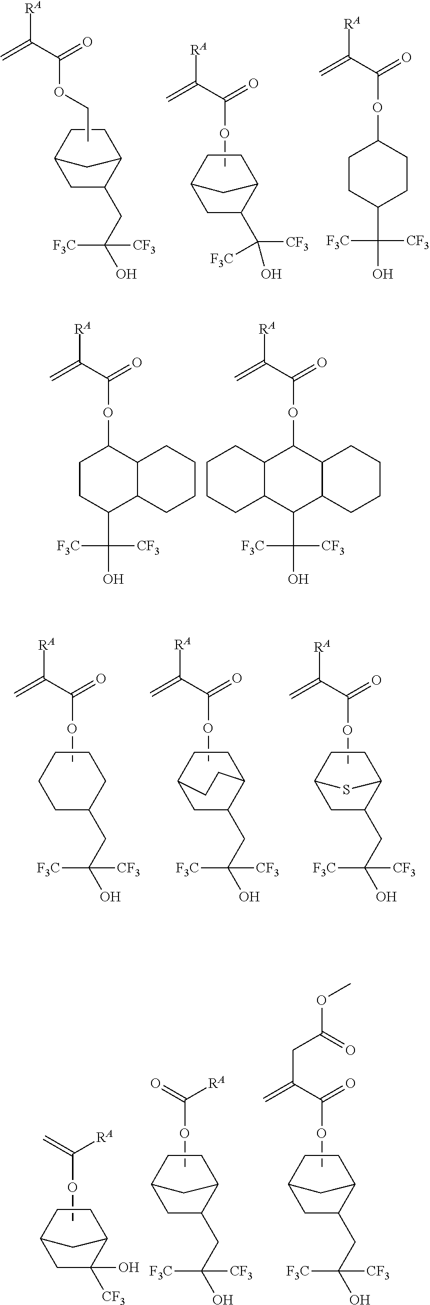

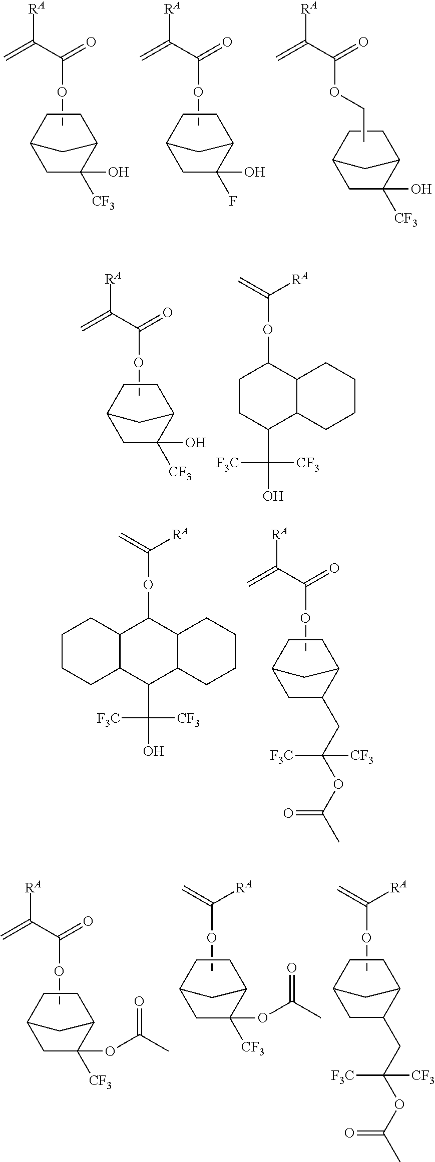

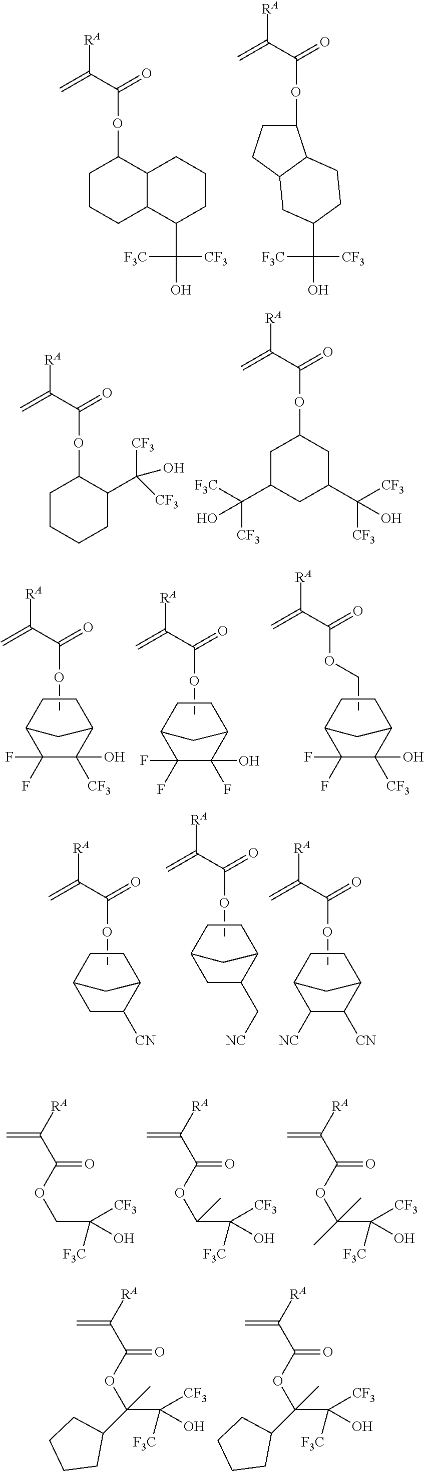

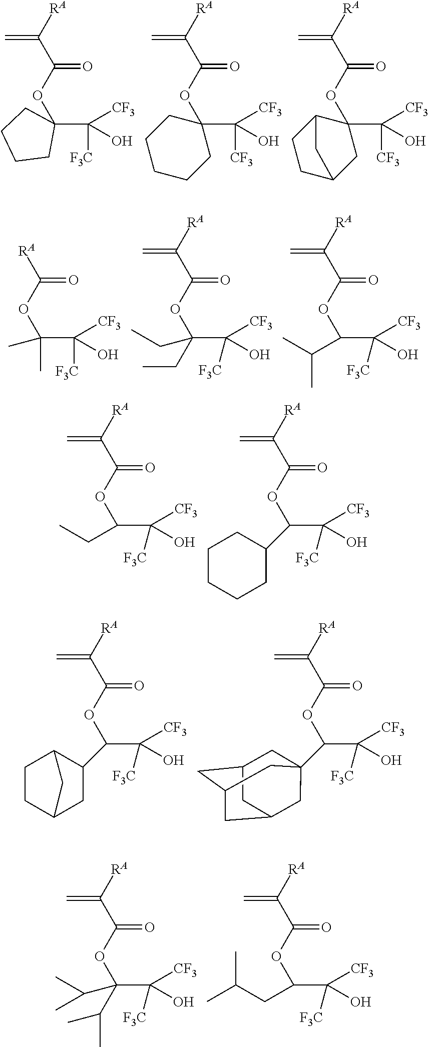

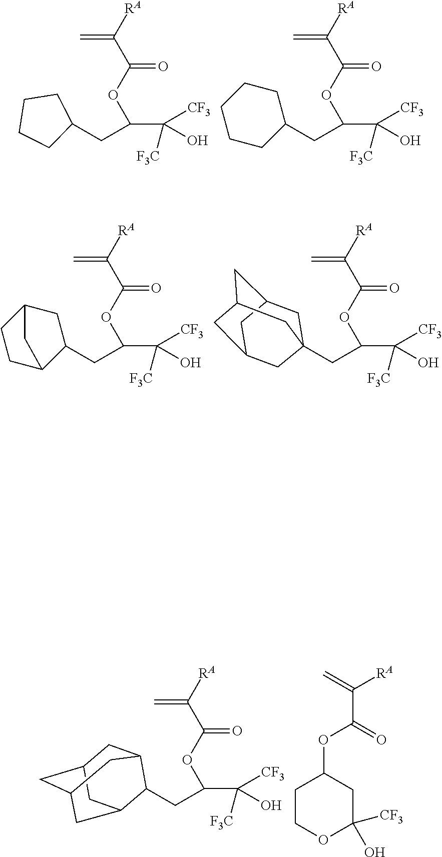

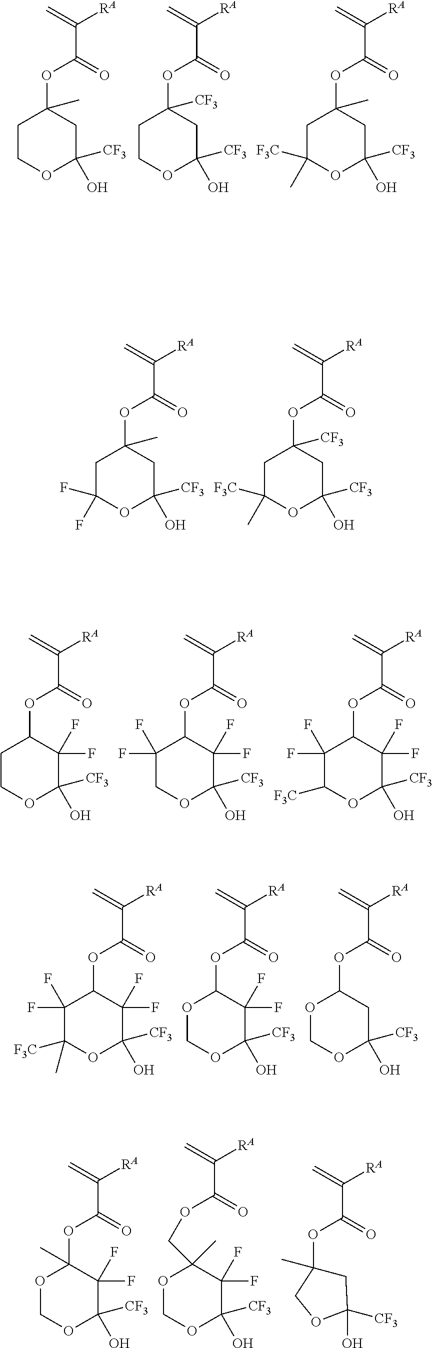

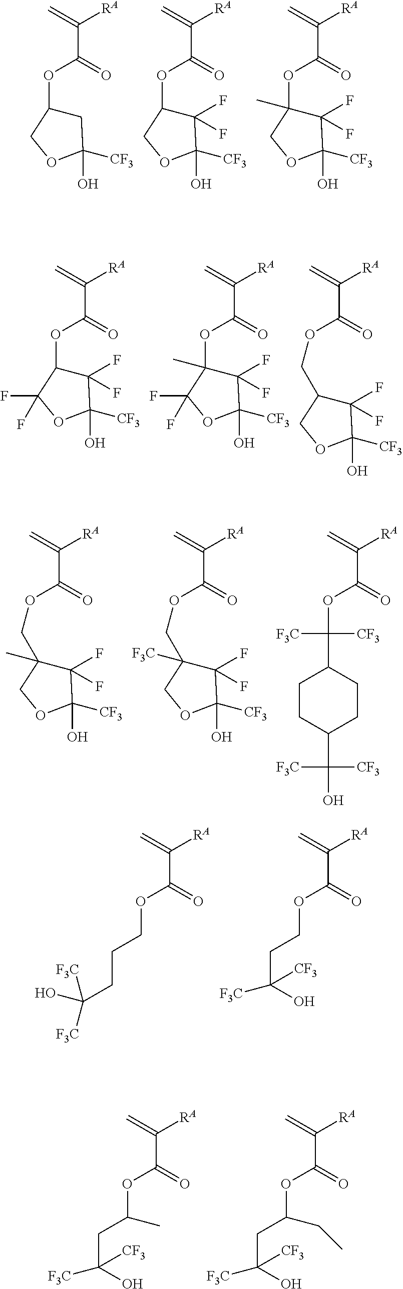

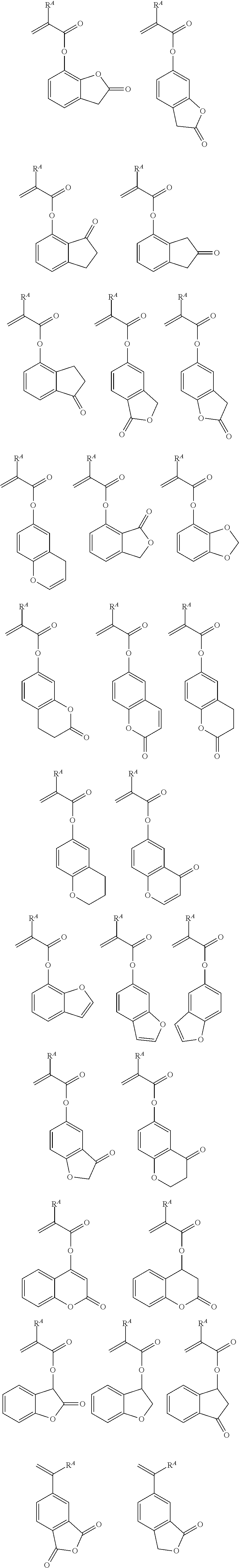

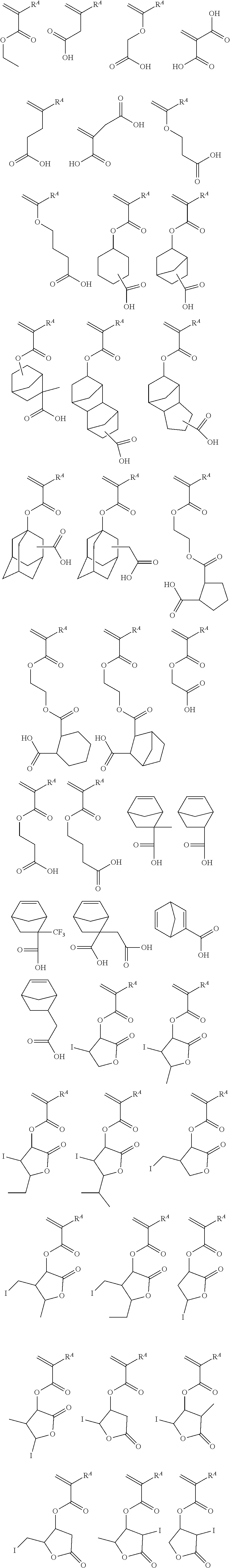

The lower limit of the content of the structural unit (V) (when a plurality of types is contained, the total content thereof is taken) is preferably 5 mol %, more preferably 8 mol %, and still more preferably 10 mol % based on all structural units composing the radiation-sensitive acid generating resin. The upper limit of the content is preferably 40 mol %, more preferably 30 mol %, and still more preferably 20 mol %. When the content of the structural unit (V) is adjusted to within the above range, the pattern adhesiveness can be further improved.

The radiation-sensitive acid generating resin can be synthesized, for example, by polymerizing monomers to afford the above-described structural units in an organic solvent by heating with addition of a radical polymerization initiator. In the polymerization, a known polymerization initiator can be used.

When hydroxystyrene or hydroxyvinylnaphthalene is copolymerized, acetoxystyrene or acetoxyvinylnaphthalene may be used instead of hydroxystyrene or hydroxyvinylnaphthalene, and an acetoxy group may be deprotected by the alkali hydrolysis after polymerization to form a hydroxystyrene unit or a hydroxyvinylnaphthalene unit.

The lower limit of the polystyrene-equivalent weight average molecular weight (Mw) of the radiation-sensitive acid generating resin as measured by gel permeation chromatography (GPC) using THF as a solvent is preferably 2,000, and more preferably 4,000. The upper limit of the Mw is preferably 30,000, and more preferably 15,000. When the Mw is in the above range, the patternability and heat resistance of a resist material are good.

Furthermore, in a case where the radiation-sensitive acid generating resin has a wide molecular weight distribution (Mw/Mn), since a low molecular weight or high molecular weight polymer is present, there is a risk that foreign matters may be found on a pattern or the shape of the pattern may be deteriorated after exposure. Since the influence of Mw and molecular weight distribution tends to increase as the pattern rule becomes finer, in order to obtain a resist material suitably used for fine pattern dimensions, the molecular weight distribution of the radiation-sensitive acid generating resin is preferably a narrow dispersion of 1.0 to 2.0, particularly 1.0 to 1.8.

The radiation-sensitive acid generating resin may contain two or more polymers differing in composition ratio, Mw, and molecular weight distribution.

The lower limit of the content of the radiation-sensitive acid generating resin in the radiation-sensitive resin composition is preferably 75% by mass, more preferably 80% by mass, and still more preferably 85% by mass based on the amount of the radiation-sensitive resin composition excluding the solvent contained therein. The upper limit of the content is preferably 99% by mass, and more preferably 95% by mass.

### <Radiation-Sensitive Acid Generator>

The radiation-sensitive resin composition may contain a radiation-sensitive acid generator. The radiation-sensitive acid generator is preferably represented by the following formula (A-1) or (A-2).

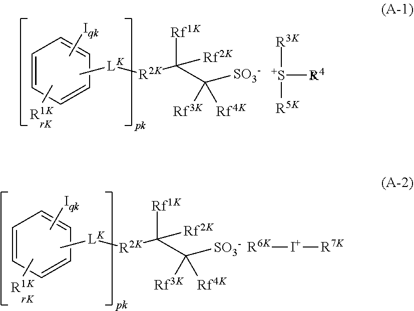

In the formulas (A-1) and (A-2), L^{K} is a single bond, an ether linkage, an ester linkage, or an alkylene group having 1 to 6 carbon atoms optionally containing an ether linkage or an ester linkage. The alkylene group may be linear, branched, or cyclic.

R^{1K} is a hydroxy group, a carboxy group, a fluorine atom, a chlorine atom, a bromine atom, or an amino group; or is an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, or an alkylsulfonyloxy group having 1 to 20 carbon atoms, each optionally containing a fluorine atom, a chlorine atom, a bromine atom, a hydroxy group, an amino group, or an alkoxy group having 1 to 10 carbon atoms; or is —NR^{8K}—C(═O)—R⁹ or —NR^{8K}—C(═O)—O—R^{9K}, wherein R^{8K} is a hydrogen atom or an alkyl group having 1 to 6 carbon atoms and optionally containing a halogen atom, a hydroxy group, an alkoxy group having 1 to 6 carbon atoms, an acyl group having 2 to 6 carbon atoms, or an acyloxy group having 2 to 6 carbon atoms, and R^{9K} is an alkyl group having 1 to 16 carbon atoms, an alkenyl group having 2 to 16 carbon atoms, or an aryl group having 6 to 12 carbon atoms and optionally contains a halogen atom, a hydroxy group, an alkoxy group having 1 to 6 carbon atoms, an acyl group having 2 to 6 carbon atoms, or an acyloxy group having 2 to 6 carbon atoms. The alkyl group, alkoxy group, alkoxycarbonyl group, acyloxy group, acyl group, and alkenyl group may be linear, branched, or cyclic.

Among them, R^{1K} is preferably a hydroxy group, —NR^{8K}—C(═O)—R^{9K}, a fluorine atom, a chlorine atom, a bromine atom, a methyl group, a methoxy group, or the like.

R^{2K} is a single bond or a divalent linking group having 1 to 20 carbon atoms when pk is 1, and is a trivalent or tetravalent linking group having 1 to 20 carbon atoms when pk is 2 or 3, and the linking groups may contain an oxygen atom, a sulfur atom, or a nitrogen atom.

Rf^{1K} to Rf^{4K} are each independently a hydrogen atom, a fluorine atom, or a trifluoromethyl group, and at least one of Rf^{1K} to Rf^{4K} is a fluorine atom or a trifluoromethyl group. Rf^{1K} and Rf^{2K} may be combined to form a carbonyl group. In particular, both Rf^{3K} and Rf^{4K} are preferably fluorine atoms.

R^{3K}, R^{4K}, R^{5K}, R^{6K}, and R^{7K} are each independently a monovalent hydrocarbon group having 1 to 20 carbon atoms and optionally containing a heteroatom. When the onium cation moiety of the radiation-sensitive acid generator has fluorine, at least one of R^{3K}, R^{4K}, and R^{5K} contains one or more fluorine atoms, and at least one of R^{6K} and R^{7K} contains one or more fluorine atoms. Any two among R^{3K}, R^{4K}, and R^{5K} may be bonded to each other to form a ring together with a sulfur atom to which two thereof are bonded. The monovalent hydrocarbon group may be linear, branched, or cyclic, and examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be replaced by a hydroxy group, a carboxy group, a halogen atom, a cyano group, an amide group, a nitro group, a mercapto group, a sultone group, a sulfone group, or a sulfonium salt-containing group, and some of the carbon atoms of these groups may be replaced by an ether linkage, an ester linkage, a carbonyl group, a carbonate group, or a sulfonate ester linkage.

pk is an integer satisfying 1≤pk≤3. qk and rk are integers satisfying 0≤qk≤5, 0≤rk≤3, and 0≤qk+rk≤5. qk is preferably an integer satisfying 1≤qk≤3, more preferably 2 or 3. rk is preferably an integer satisfying 0≤rk≤2.

Examples of the organic acid anion moiety of the radiation-sensitive acid generators represented by the formulas (A-1) and (A-2) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or another substituent.

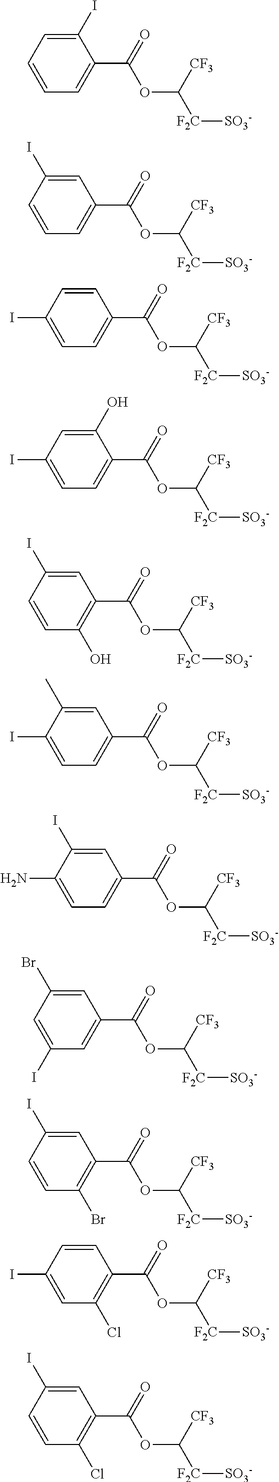

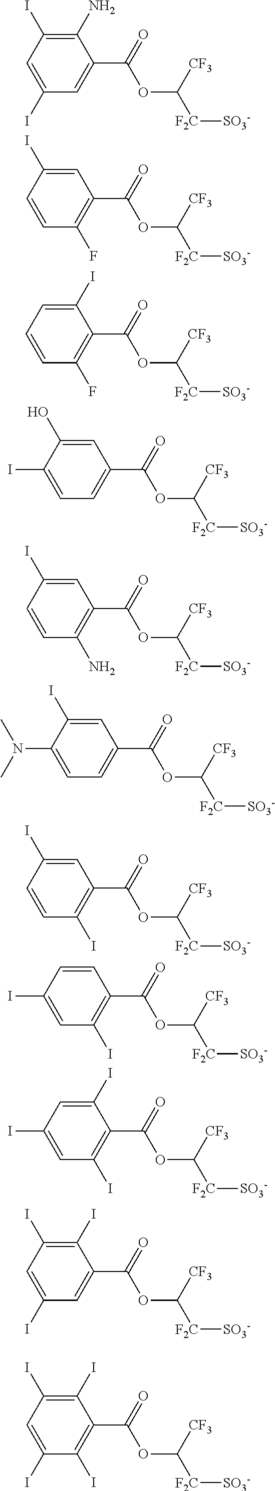

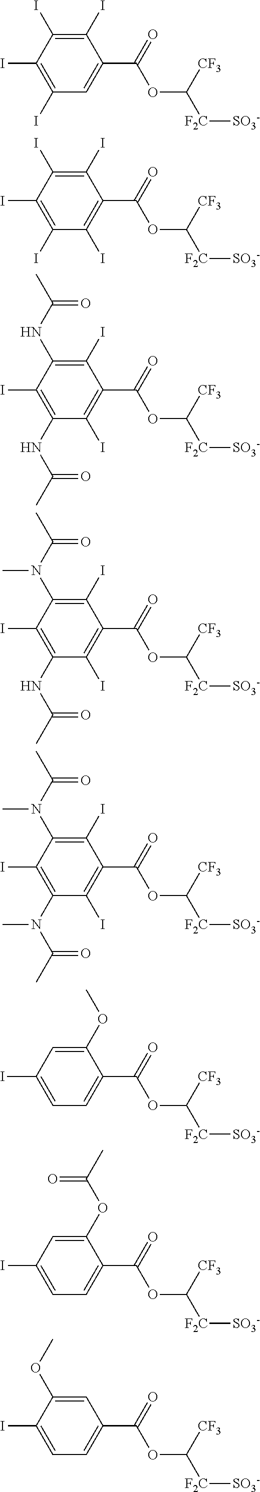

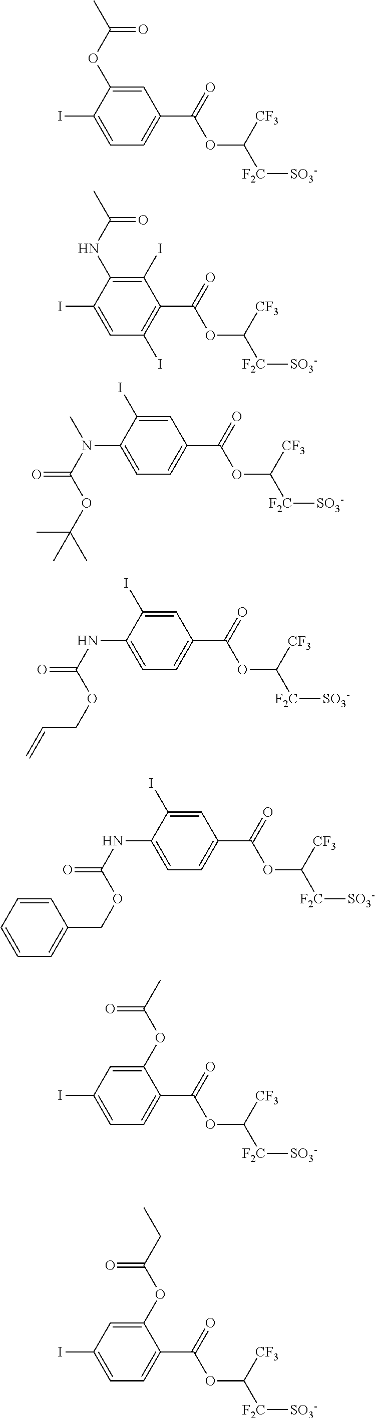

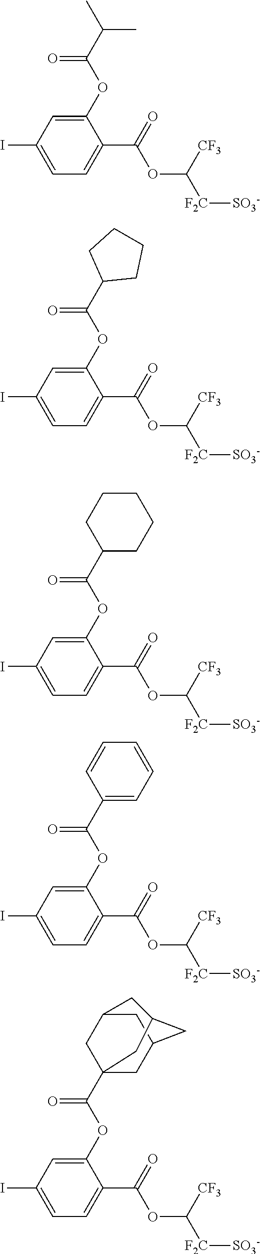

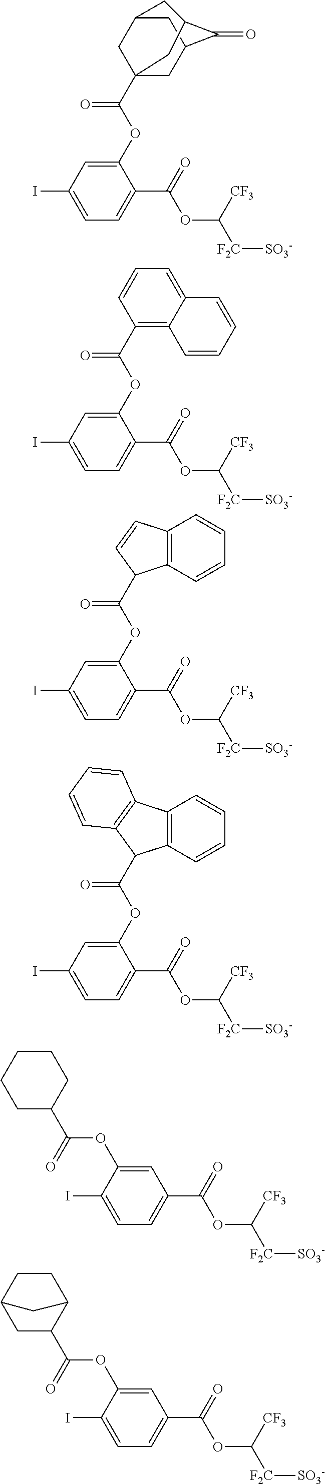

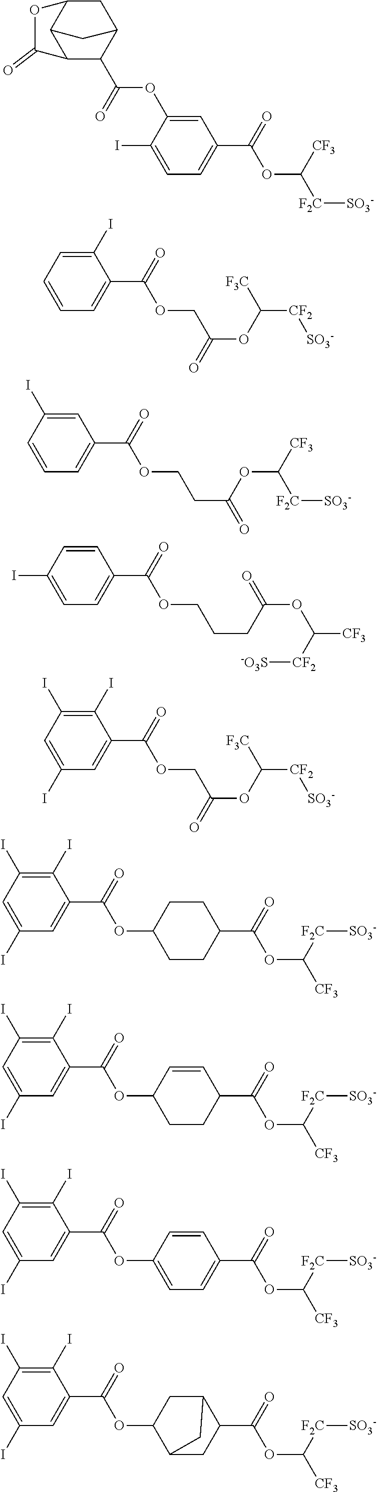

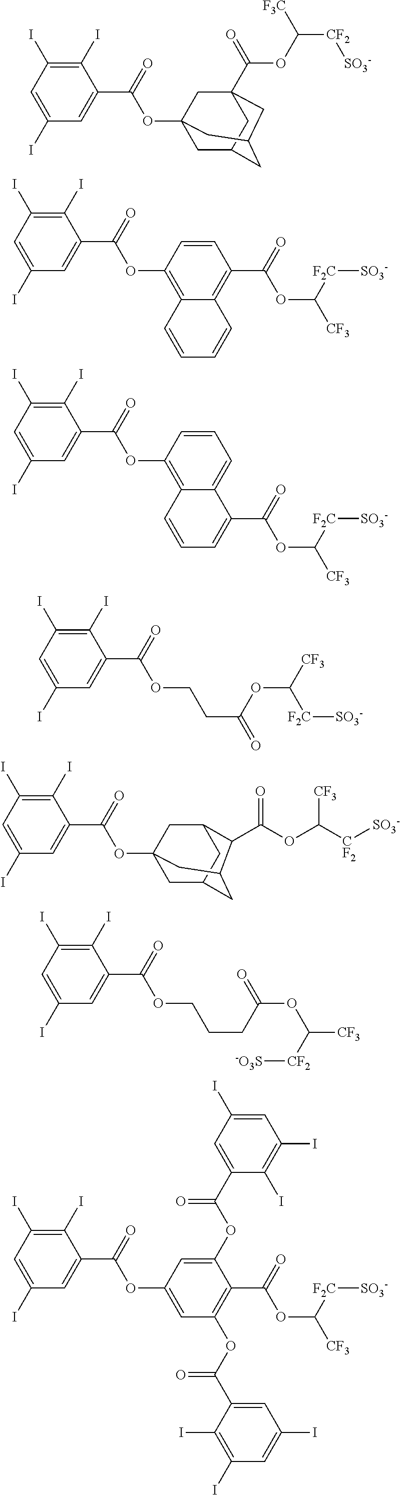

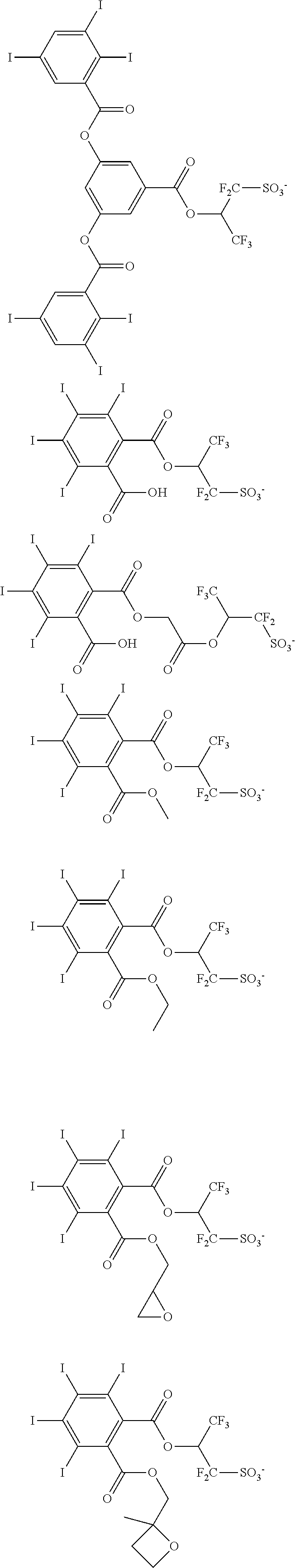

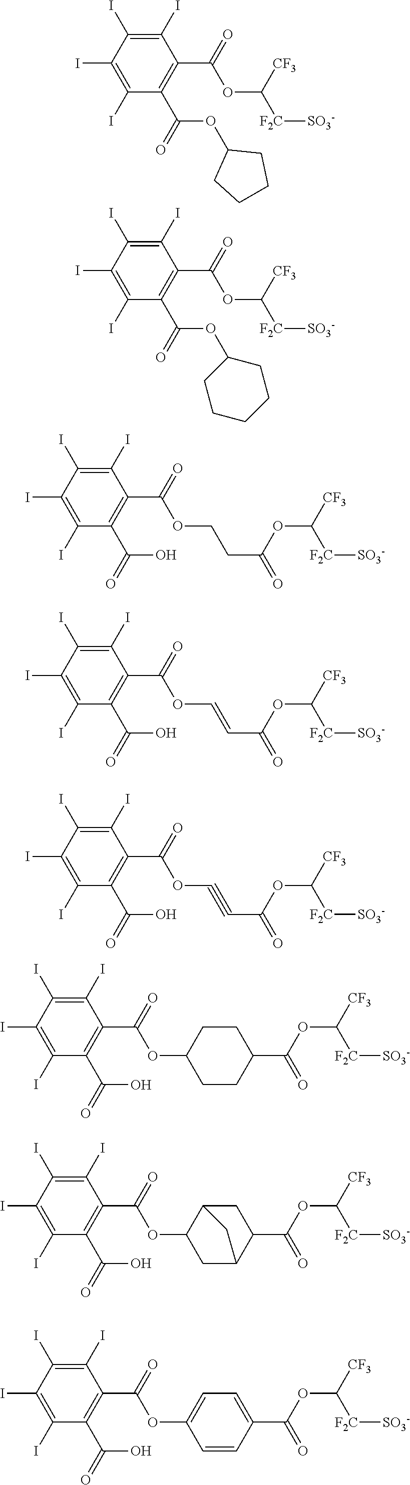

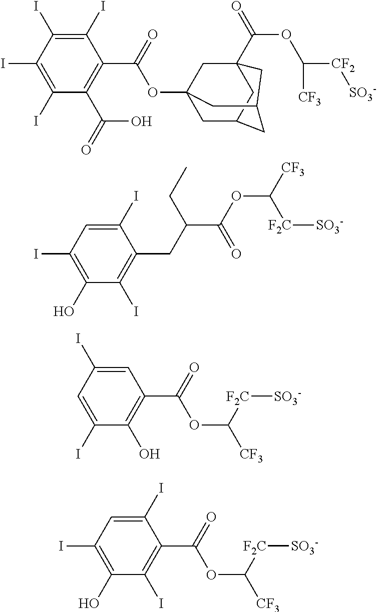

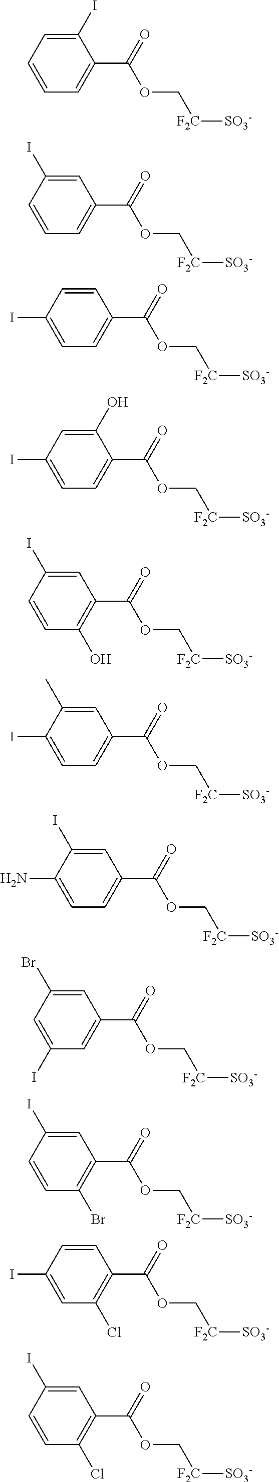

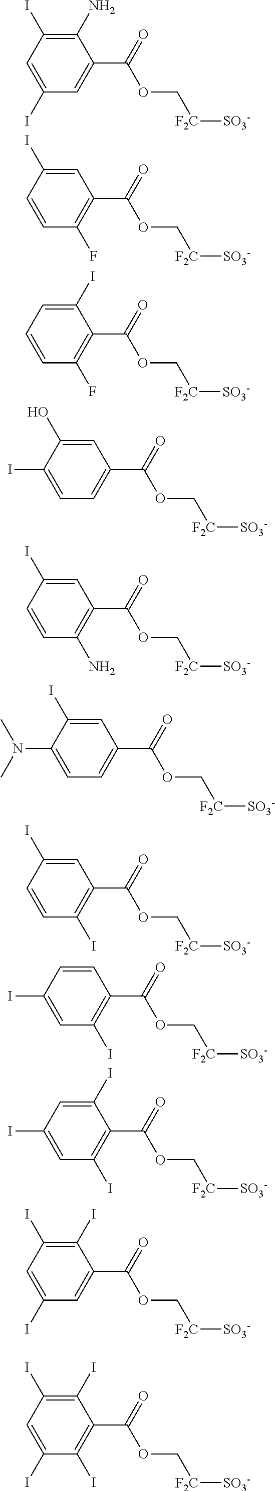

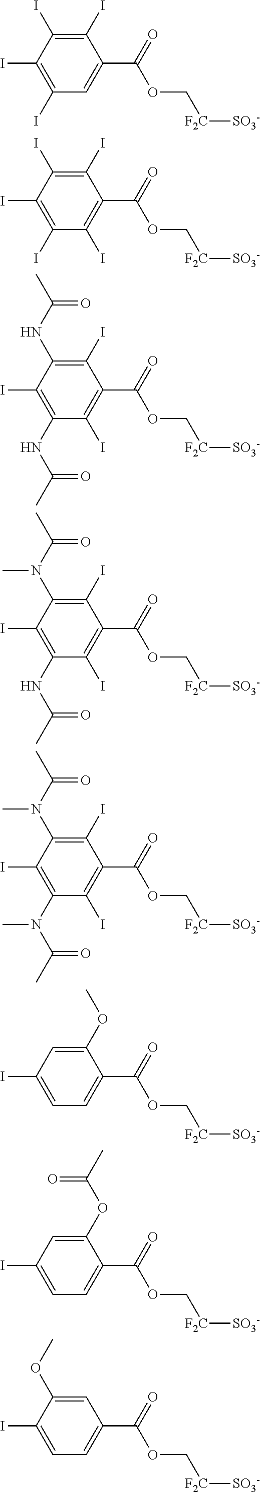

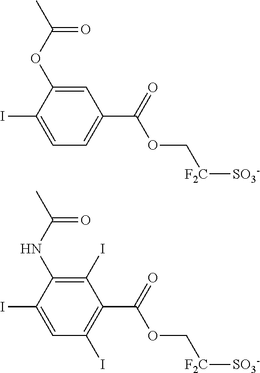

As the onium cation moieties in the radiation-sensitive acid generators represented by the formulas (A-1) and (A-2), an onium cation moiety in a structural unit (II-1) and a structural unit (II-2) of a radiation-sensitive acid generating resin can be suitably employed.

The radiation-sensitive acid generators represented by the above formulas (A-1) and (A-2) can also be synthesized by a known method, particularly by a salt exchange reaction. A known radiation-sensitive acid generator may also be used as long as the effect of the present invention is not impaired.

These radiation-sensitive acid generators may be used singly, or two or more thereof may be used in combination. The lower limit of the content of the radiation-sensitive acid generator is preferably 0.1 parts by mass, more preferably 0.5 parts by mass, and still more preferably 1 part by mass based on 100 parts by mass of the radiation-sensitive acid generating resin (when a resin described below is contained, the total amount thereof is taken as the basis). The upper limit of the content is preferably 10 parts by mass, more preferably 8 parts by mass, and still more preferably 5 parts by mass based on 100 parts by mass of the resin. This makes it possible to exhibit superior sensitivity or CDU performance when forming a resist pattern.

### <Acid Diffusion Controlling Agent>

The radiation-sensitive resin composition preferably contains an acid diffusion controlling agent. The acid diffusion controlling agent generates an acid having a pKa higher than that of the acid generated from the radiation-sensitive acid generating resin or the radiation-sensitive acid generator through irradiation with radiation. The acid diffusion controlling agent is preferably represented by the following formula (S-1) or (S-2).

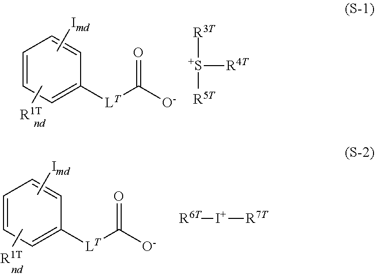

In the formulas (S-1) and (S-2), R^{1T} is a hydrogen atom, a hydroxy group, a fluorine atom, a chlorine atom, an amino group, a nitro group, or a cyano group; or an alkyl group having 1 to 6 carbon atoms, an alkoxy group having 1 to 6 carbon atoms, an acyloxy group having 2 to 6 carbon atoms, or an alkylsulfonyloxy group having 1 to 4 carbon atoms, which may be substituted with a halogen atom; or —NR^{TA}—C(═O)—R^{TB} or —NR^{TA}—C(═O)—O—R^{TB}. R^{TA} is a hydrogen atom or an alkyl group having 1 to 6 carbon atoms, and R^{TB} is an alkyl group having 1 to 6 carbon atoms or an alkenyl group having 2 to 8 carbon atoms.

The alkyl group having 1 to 6 carbon atoms may be linear, branched, or cyclic, and examples thereof include a methyl group, an ethyl group, a n-propyl group, an isopropyl group, a cyclopropyl group, a n-butyl group, an isobutyl group, a sec-butyl group, a tert-butyl group, a cyclobutyl group, a n-pentyl group, a cyclopentyl group, a n-hexyl group, and a cyclohexyl group. Examples of the alkyl moiety of the alkoxy group having 1 to 6 carbon atoms, the acyloxy group having 2 to 7 carbon atoms, and the alkoxycarbonyl group having 2 to 7 carbon atoms include those the same as the examples of the alkyl group described above, and examples of the alkyl moiety of the alkylsulfonyloxy group having 1 to 4 carbon atoms include those having 1 to 4 carbon atoms among the examples of the alkyl group described above. The alkenyl group having 2 to 8 carbon atoms may be linear, branched, or cyclic, and examples thereof include a vinyl group, a 1-propenyl group, and a 2-propenyl group. Among them, a fluorine atom, a chlorine atom, a hydroxy group, an amino group, an alkyl group having 1 to 3 carbon atoms, an alkoxy group having 1 to 3 carbon atoms, an acyloxy group having 2 to 4 carbon atoms, —NR^{TA}—C(═O)—R^{TB}, and —NR^{TA}—C(═O)—O—R^{TB} are preferable as R^{1T}.

R^{3T}, R^{4T}, R^{5T}, R^{6T}, and R^{7T} are each independently a monovalent hydrocarbon group having 1 to 20 carbon atoms and optionally containing a heteroatom. When the onium cation moiety of the acid diffusion controlling agent has a fluorine atom, at least one among R^{3T}, R^{4T}, and R^{5T} contains one or more fluorine atoms, and at least one of R^{6T} and R^{7T} contains one or more fluorine atoms. Any two among R^{3T}, R^{4T}, and R^{5T} may be bonded to each other to form a ring together with a sulfur atom to which two thereof are bonded. The monovalent hydrocarbon group may be linear, branched, or cyclic, and examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be replaced by a hydroxy group, a carboxy group, a halogen atom, a cyano group, an amide group, a nitro group, a mercapto group, a sultone group, a sulfone group, or a sulfonium salt-containing group, and some of the carbon atoms of these groups may be replaced by an ether linkage, an ester linkage, a carbonyl group, a carbonate group, or a sulfonate ester linkage.

L^{T} is a single bond or a divalent linking group having 1 to 20 carbon atoms, and may contain an ether linkage, a carbonyl group, an ester linkage, an amide linkage, a sultone ring, a lactam ring, a carbonate linkage, a halogen atom, a hydroxy group, or a carboxy group.

md and nd are integers satisfying 0≤md≤5, 0≤nd≤3, and 0≤md+nd≤5, and preferably integers satisfying 1≤md≤3 and 0≤nd≤2.

Examples of the organic acid anion moiety of the acid diffusion controlling agent represented by the formula (S-1) or (S-2) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or another substituent.

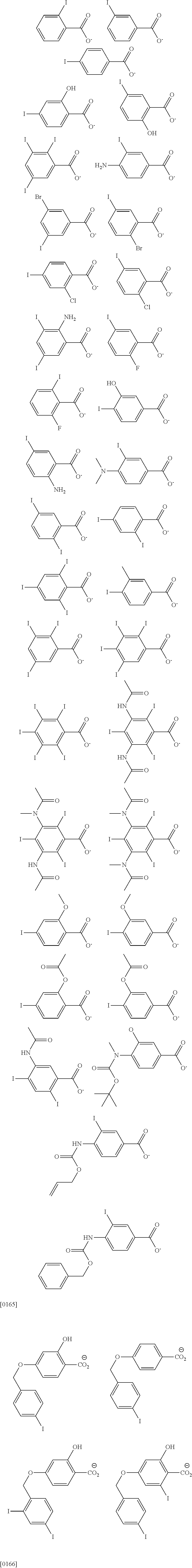

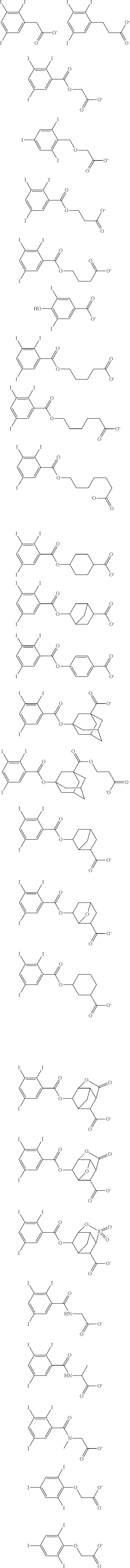

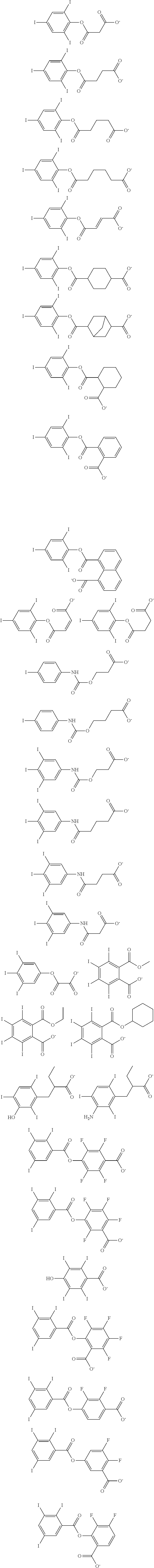

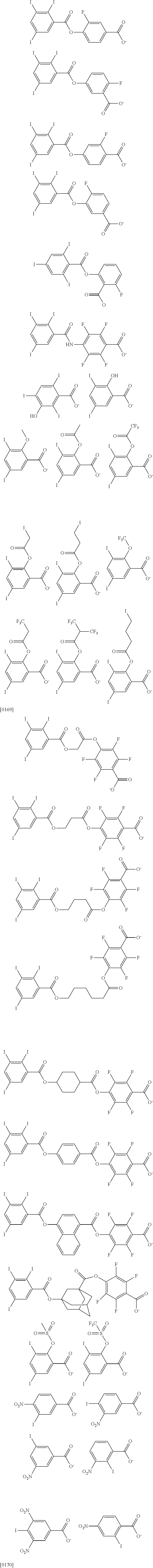

As the onium cation moieties in the acid diffusion controlling agents represented by the formulas (S-1) and (S-2), onium cation moieties in the structural unit (II-1) and the structural unit (II-2) of the radiation-sensitive acid generating resin can be suitably employed.

The acid diffusion controlling agents represented by the formulas (S-1) and (S-2) can be synthesized by a known method, particularly by a salt exchange reaction. A known acid diffusion controlling agent may be used as long as the effect of the present invention is not impaired.

These acid diffusion controlling agents may be used singly, or two or more thereof may be used in combination. The lower limit of the content of the acid diffusion controlling agent is preferably 1 part by mass, more preferably 2 parts by mass, and still more preferably 4 parts by mass based on 100 parts by mass of the radiation-sensitive acid generating resin. The upper limit of the content is preferably 15 parts by mass, more preferably 10 parts by mass, and still more preferably 8 parts by mass. This makes it possible to exhibit superior sensitivity or CDU performance when forming a resist pattern.

### <Other Resins>

The radiation-sensitive resin composition according to the present embodiment may contain, as another resin, a resin having higher content by mass of fluorine atoms than the above-described base resin (hereinafter, also referred to as a “high fluorine-content resin”). When the radiation-sensitive resin composition includes the high fluorine-content resin, the high fluorine-content resin can be localized in the surface layer of a resist film compared to the base resin, and as a result, the state of the surface of the resist film and the component distribution in the resist film can be controlled to a desired state.

The high fluorine-content resin preferably has a structural unit represented by the following formula (6) (hereinafter, also referred to as “structural unit (VI)”). In addition, for example, the high fluorine-containing resin may, as necessary, have at least one of the structural units (III) to (V) in the base resin.

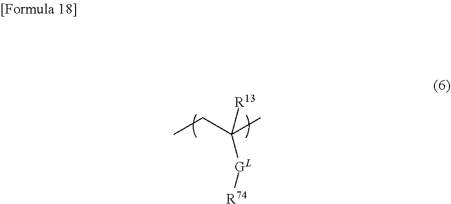

In the above formula (6), R⁷³ is a hydrogen atom, a methyl group, or a trifluoromethyl group. GL is a single bond, an oxygen atom, a sulfur atom, —COO—, —SO₂ONH—, —CONH—, or —OCONH—. R⁷⁴ is a monovalent fluorinated chain hydrocarbon group having 1 to 20 carbon atoms or a monovalent fluorinated alicyclic hydrocarbon group having 3 to 20 carbon atoms.

As R⁷³, a hydrogen atom and a methyl group are preferable from the viewpoint of the copolymerizability of a monomer that affords the structural unit (VI), and a methyl group is more preferable.

As the GL, a single bond and —COO— are preferable from the viewpoint of the copolymerizability of a monomer that affords the structural unit (VI), and —COO— is more preferable.

Examples of the monovalent fluorinated chain hydrocarbon group having 1 to 20 carbon atoms represented by R⁷⁴ may include monovalent fluorinated chain hydrocarbon groups in which some or all of the hydrogen atoms of a linear or branched chain alkyl group having 1 to 20 carbon atoms are replaced by fluorine atoms.

Examples of the monovalent fluorinated alicyclic hydrocarbon group having 3 to 20 carbon atoms represented by R⁷⁴ may include monovalent fluorinated alicyclic hydrocarbon groups in which some or all of the hydrogen atoms of a mono- or polycyclic hydrocarbon group having 3 to 20 carbon atoms are replaced by fluorine atoms.

As the R⁷⁴, fluorinated chain hydrocarbon groups are preferable, fluorinated alkyl groups are more preferable, and a 2,2,2-trifluoroethyl group, a 1,1,1,3,3,3-hexafluoropropyl group, a 5,5,5-trifluoro-1,1-diethylpentyl group, and a 1,1,1,2,2,3,3-heptafluoro-6-methylheptan-4-yl group are still more preferable.

When the high fluorine-content resin has the structural unit (VI), the lower limit of the content of the structural unit (VI) is preferably 50 mol %, more preferably 60 mol %, and still more preferably 70 mol % based on the total amount of all structural units constituting the high fluorine-content resin. The upper limit of the content is preferably 100 mol %, more preferably 95 mol %, and still more preferably 90 mol %. When the content of the structural unit (VI) is adjusted to within the above range, the mass content of fluorine atoms in the high fluorine-content resin can more appropriately be adjusted and the localization in the surface layer of a resist film can be further promoted.

The lower limit of the Mw of the high fluorine-content resin is preferably 1,000, more preferably 2,000, still more preferably 3,000, and particularly preferably 5,000. The upper limit of the Mw is preferably 50,000, more preferably 30,000, still more preferably 20,000, and particularly preferably 15,000.

The Mw/Mn of the high fluorine-content resin is usually 1 or more, and preferably 1.1 or more. The Mw/Mn is usually 5 or less, preferably 3 or less, more preferably 2.5 or less, and still more preferably 2.2 or less.

The lower limit of the content of the high fluorine-content resin is preferably 0.5 parts by mass, more preferably 1 part by mass, and still more preferably 2 parts by mass based on 100 parts by mass of the radiation-sensitive acid generating resin. The upper limit of the content is preferably 10 parts by mass, more preferably 8 parts by mass, and still more preferably 5 parts by mass. When the content of the high fluorine-content resin is adjusted to within the above range, the high fluorine-content resin can be more effectively localized in the surface layer of a resist film, and as a result, the elusion of a top portion of the pattern is suppressed during development and the rectangularity of the pattern can be enhanced. The radiation-sensitive resin composition may contain one type or two or more types of high fluorine-content resin.

### (Method for Synthesizing High Fluorine-Content Resin)

The high fluorine-content resin can be synthesized by the same method as the method for synthesizing the base resin described above.

### <Solvent>

The radiation-sensitive composition according to the present embodiment contains a solvent. The solvent is not particularly limited as long as it is a solvent capable of dissolving or dispersing the base polymer, additives contained as desired, and the like.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
monoalcohol-based solvents having 1 to 18 carbon atoms, such as iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
polyhydric alcohol-based solvents having 2 to 18 carbon atoms, such as ethylene glycol, 1,2-propylene glycol, 2-methyl-2,4-pentanediol, 2,5-hexanediol, diethylene glycol, dipropylene glycol, triethylene glycol, and tripropylene glycol; and
partially etherized polyhydric alcohol-based solvents obtained by etherifying some of hydroxy groups of the polyhydric alcohol-based solvent.

Examples of the ether-based solvent include:
dialkyl ether-based solvents, such as diethyl ether, dipropyl ether, and dibutyl ether;
cyclic ether-based solvents, such as tetrahydrofuran and tetrahydropyran;
aromatic ring-containing ether-based solvents, such as diphenyl ether and anisole (methyl phenyl ether); and
etherized polyhydric alcohol-based solvents obtained by etherifying a hydroxy group of the polyhydric alcohol-based solvent.

Examples of the ketone-based solvent include chain ketone-based solvents, such as acetone, butanone, and methyl-iso-butyl ketone;
cyclic ketone-based solvents, such as cyclopentanone, cyclohexanone, and methylcyclohexanone; and
2,4-pentanedione, acetonylacetone, and acetophenone.

Examples of the amide-based solvent include cyclic amide-based solvents, such as N,N′-dimethylimidazolidinone and N-methylpyrrolidone; and
chain amide-based solvents, such as N-methylformamide, N,N-dimethylformamide, N,N-diethylformamide, acetamide, N-methylacetamide, N,N-dimethylacetamide, and N-methylpropionamide.

Examples of the ester-based solvent include:
monocarboxylic acid ester-based solvents, such as n-butyl acetate, and ethyl lactate;
partially etherized polyhydric alcohol acetate-based solvents, such as diethylene glycol mono-n-butyl ether acetate, propylene glycol monomethyl ether acetate, and dipropylene glycol monomethyl ether acetate;
lactone-based solvents, such as γ-butyrolactone and valerolactone;
carbonate-based solvents, such as diethyl carbonate, ethylene carbonate, and propylene carbonate; and
polyvalent carboxylic acid diester-based solvents, such as propylene glycol diacetate, methoxytriglycol acetate, diethyl oxalate, ethyl acetoacetate, and diethyl phthalate.

Examples of the hydrocarbon-based solvent include:
aliphatic hydrocarbon-based solvents, such as n-hexane, cyclohexane, and methylcyclohexane; and
aromatic hydrocarbon-based solvents, such as benzene, toluene, di-iso-propylbenzene, and n-amylnaphthalene.

Among them, an ester-based solvent, a ketone-based solvent, an alcohol-based solvent, and an ether-based solvent are preferable, a partially etherized polyhydric alcohol acetate-based solvent, a cyclic ketone-based solvent, a lactone-based solvent, a monoalcohol-based solvent having 1 to 18 carbon atoms, a partially etherized polyhydric alcohol-based solvent, and a monocarboxylic acid ester-based solvent are more preferable, and propylene glycol monomethyl ether acetate, cyclohexanone, γ-butyrolactone, propylene glycol monomethyl ether, diacetone alcohol, and ethyl lactate are still more preferable. The radiation-sensitive resin composition may contain one type or two or more types of solvent.

### <Other Optional Components>

The radiation-sensitive resin composition may contain, in addition to the components, other optional components. Examples of other optional components may include a cross-linking agent, a localization enhancing agent, a surfactant, an alicyclic backbone-containing compound, and a sensitizer. These other optional components may be used singly, or two or more thereof may be used in combination.

### <Method for Preparing Radiation-Sensitive Composition>

The radiation-sensitive resin composition can be prepared, for example, by mixing the radiation-sensitive acid generating resin and the solvent, and if necessary, the optional component at a prescribed ratio. The radiation-sensitive resin composition is, after the mixing, preferably filtered through, for example, a filter having a pore size of approximately 0.05 μm to 0.4 μm. The solid matter concentration of the radiation-sensitive resin composition is usually 0.1% by mass to 50% by mass, preferably 0.5% by mass to 30% by mass, more preferably 1% by mass to 20% by mass.

### <Pattern Forming Method>

A pattern forming method according to the present embodiment includes:
a step (1) of applying the radiation-sensitive resin composition directly or indirectly on a substrate to form a resist film (hereinafter also referred to as “resist film forming step”);
a step (2) of exposing the resist film to light (hereinafter also referred to as “exposure step”); and
a step (3) of developing the exposed resist film with a developer (hereinafter also referred to as “development step”).

In accordance with this pattern formation method, a high-quality resist pattern can be formed because of the use of the radiation-sensitive resin composition superior in sensitivity and CDU performance in the exposure step. Hereinbelow, each of the steps will be described.

### [Resist Film Forming Step]

In this step (the step (1)), a resist film is formed from the radiation-sensitive resin composition. Examples of the substrate on which the resist film is formed may include those traditionally known in the art, including a silicon wafer, silicon dioxide, and a wafer coated with aluminum. An organic or inorganic antireflective film disclosed in, for example, JP-B-6-12452 or JP-A-59-93448 may be formed on the substrate. Examples of an applicating method may include a rotary coating (spin coating), flow casting, and roll coating. After the application, prebaking (PB) may be performed to volatilize the solvent in the coating film, as necessary. The temperature of PB is usually from 60° C. to 160° C., preferably from 80° C. to 140° C. The duration of PB is usually from 5 seconds to 600 seconds, preferably from 10 seconds to 300 seconds. The thickness of the resist film formed is preferably from 10 nm to 1,000 nm, more preferably from 10 nm to 500 nm.

When the subsequent exposure step is performed with radiation having a wavelength of 50 nm or less, it is preferable to use a resin having at least one among the structural units (III) to (V) as the base resin in the composition.

### [Exposure Step]

In this step (the step (2)), the resist film formed in the resist film forming step as the step (1) is exposed by irradiating with radiation through a photomask (possibly through an immersion medium such as water). Examples of the radiation to be used for the exposure may include an electromagnetic wave including visible ray, ultraviolet ray, far ultraviolet ray, extreme ultraviolet ray (EUV), X ray, and γ ray; and charged particle radiation such as an electron beam and α ray. Among them, far ultraviolet ray, an electron beam, or EUV is preferable. ArF excimer laser light (wavelength is 193 nm), KrF excimer laser light (wavelength is 248 nm), an electron beam, or EUV is more preferable. An electron beam having a wavelength of 50 nm or less, which is identified as the next generation exposing technology, or EUV is further preferable.

After the exposure, post exposure bake (PEB) is preferably performed to promote the dissociation of the acid-dissociable group of the resin by an acid generated from the radiation-sensitive acid generator through exposure to light in the exposed part of the resist film. As a result of the PEB, there is generated a difference in solubility into a developer between the exposed area and the unexposed area. The temperature of PEB is usually from 50° C. to 180° C., preferably from 80° C. to 150° C. The duration of PEB is usually from 5 seconds to 600 seconds, preferably from 10 seconds to 300 seconds.

### [Development Step]

In this step (the step (3)), the resist film exposed in the exposure step as the step (2) is developed with a developer. By this step, the predetermined resist pattern can be formed. After the development, the resist pattern is generally washed with a rinse solution such as water or alcohol, and then dried.

Examples of the developer used for the development may include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferable, and a 2.38% by mass aqueous TMAH solution is more preferable.

In the case of organic solvent development, examples of the solvent may include organic solvents such as hydrocarbon-based solvents, ether-based solvents, ester-based solvents, ketone-based solvents, and alcohol-based solvents, and solvents containing an organic solvent. Examples of the organic solvent may include one, two or more solvents listed as the solvent for the radiation-sensitive resin composition. Among them, ester-based solvents and ketone-based solvents are preferable. As the ester-based solvents, acetate-based solvents are preferable, and n-butyl acetate and amyl acetate are more preferable. As the ketone-based solvents, chain ketones are preferable, and 2-heptanone is more preferable. The content of the organic solvent in a developer is preferably 80% by mass or more, more preferably 90% by mass or more, still more preferably 95% by mass or more, particularly preferably 99% by mass or more. Examples of the component other than the organic solvent in the developer may include water and silicone oil.

Examples of the developing method may include a method including dipping a substrate in a tank filled with a developer for a given time (dipping method); a developing method including raising a developer on the surface of a substrate due to surface tension and leaving the raised developer for a given time (paddling method); a method including spraying a developer on the surface of a substrate (spraying method); and a method including injecting a developer on a substrate rolling at a constant rate while scanning a developer injection nozzle at a constant rate (dynamic dispensing method).

### EXAMPLES

Hereinafter, the present invention will be specifically described with reference to Synthesis Examples, Examples, and Comparative Examples, but the present invention is not limited to the following Examples. The methods for measuring physical property values are described below.

### [Mw and Mn]

The Mw and the Mn of polymers were measured by Gel Permeation Chromatography (GPC) using GPC columns manufactured by Tosoh Corporation (“G2000HXL”×2, “G3000HXL”×1, “G4000HXL”×1) under the following conditions.

Eluant: tetrahydrofuran (manufactured by Wako Pure Chemical Industries, Ltd.)

Flow rate: 1.0 mL/min

Sample concentration: 1.0% by mass

Sample injection amount: 100 μL

Column temperature: 40° C.

Detector: differential refractometer

Reference material: monodisperse polystyrene

The structures of the radiation-sensitive acid generator PAG1 and the acid diffusion controlling agents Q-1 to Q-3 used for the radiation-sensitive resin compositions of Examples are shown below.

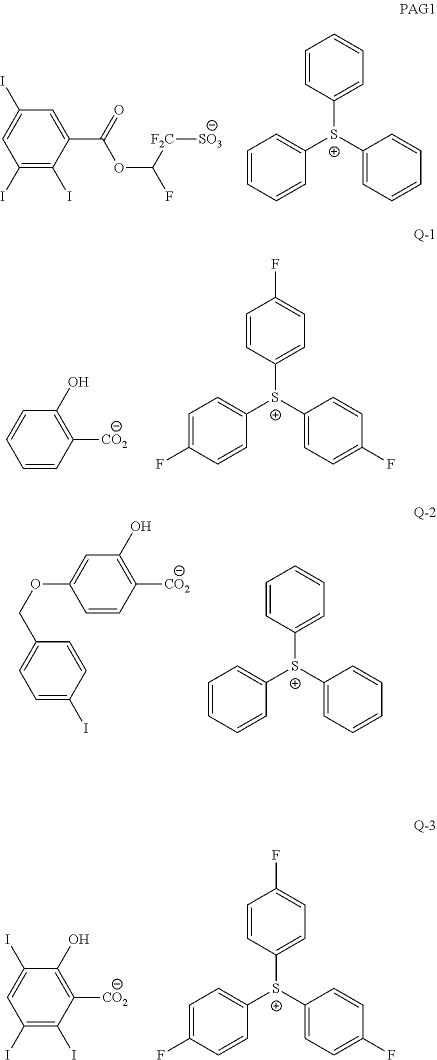

### [Synthesis Examples] Synthesis of Base Resins (P-1) to (P-13) and (Pc-1) to (Pc-5)

The monomers given below were subjected in combination to a copolymerization reaction in a tetrahydrofuran (THF) solvent, and the reaction products were isolated and dried, affording base resins (P-1) to (P-13) and (Pc-1) to (Pc-5) having the compositions shown in Table 1. The compositions of the obtained base resins were confirmed by 1H-NMR, and the Mw and the dispersion degree (Mw/Mn) were confirmed by the above-described GPC (solvent: THF, standard: polystyrene). For example, “mc-2/mc-3=1/1” in Synthesis Example 1 means that mc-2 and mc-3 are contained at a molar ratio of 1:1, and the total thereof is 30 mol %. Thus, the composition of the base resin (P-1) is ma-1/mb-1/mc-2/mc-3/md-1=15/10/15/15/45 (molar ratio).

TABLE 1

| | | Structural unit | | Structural unit | | Structural unit | | Structural unit | | Structural unit | | | |
|---|---|---|---|---|---|---|---|---|---|---|---|---|---|
| | Base | (I) | | (II) | | (III) | | (IV) | | (V), etc. | | | Mw/ |
| | resin | Type | mol % | Type | moll % | Type | mol % | Type | mol % | Type | mol % | Mw | Mn |
| Synthesis | P-1 | ma-1 | 15 | mb-1 | 10 | mc-2/mc-3 = 1/1 | 30 | md-1 | 45 | — | — | 7900 | 1.7 |
| Example 1 | | | | | | | | | | | | | |
| Synthesis | P-2 | ma-1 | 15 | mb-2 | 10 | mc-2/mc-3 = 1/1 | 30 | md-1 | 45 | — | — | 8000 | 1.7 |
| Example 2 | | | | | | | | | | | | | |
| Synthesis | P-3 | ma-1 | 15 | mb-3 | 10 | mc-2/mc-3 = 1/1 | 30 | md-1 | 45 | — | — | 8200 | 1.7 |
| Example 3 | | | | | | | | | | | | | |
| Synthesis | P-4 | ma-1 | 15 | mb-4 | 10 | mc-2/mc-3 = 1/1 | 30 | md-1 | 45 | — | — | 8200 | 1.7 |
| Example 4 | | | | | | | | | | | | | |
| Synthesis | P-5 | ma-1 | 15 | mb-5 | 10 | mc-2/mc-3 = 1/1 | 30 | md-1 | 45 | — | — | 8100 | 1.7 |
| Example 5 | | | | | | | | | | | | | |
| Synthesis | P-6 | ma-2 | 15 | mb-1 | 10 | mc-2/mc-4 = 1/1 | 30 | md-2 | 45 | — | — | 8300 | 1.7 |
| Example 6 | | | | | | | | | | | | | |
| Synthesis | P-7 | ma-3 | 15 | mb-2 | 10 | mc-2 | 30 | md-4 | 45 | — | — | 8400 | 1.7 |
| Example 7 | | | | | | | | | | | | | |
| Synthesis | P-8 | ma-4 | 15 | mb-3 | 10 | mc-3 | 30 | md-5 | 45 | — | — | 7500 | 1.7 |
| Example 8 | | | | | | | | | | | | | |
| Synthesis | P-9 | ma-5 | 15 | mb-4 | 10 | mc-3/mc-4 = 1/1 | 30 | md-1 | 45 | — | — | 7700 | 1.7 |
| Example 9 | | | | | | | | | | | | | |
| Synthesis | P-10 | ma-6 | 15 | mb-5 | 10 | mc-4 | 30 | md-1 | 45 | — | — | 8000 | 1.7 |
| Example 10 | | | | | | | | | | | | | |
| Synthesis | P-11 | ma-1 | 40 | mb-1 | 10 | — | — | md-1 | 40 | me-1/me-2 = 1/1 | 10 | 7700 | 1.6 |
| Example 11 | | | | | | | | | | | | | |
| Synthesis | P-12 | ma-7 | 15 | mb-1 | 10 | mc-2/mc-3 = 1/1 | 30 | md-1 | 45 | — | — | 6900 | 1.7 |
| Example 12 | | | | | | | | | | | | | |
| Synthesis | P-13 | ma-8 | 15 | mb-2 | 10 | mc-2/mc-3 = 1/1 | 30 | md-1 | 45 | — | — | 7200 | 1.7 |
| Example 13 | | | | | | | | | | | | | |
| Synthesis | Pc-1 | — | — | mb-1 | 10 | mc-1/mc-2/mc-3 = 1/1/1 | 45 | md-1 | 45 | — | — | 7700 | 1.7 |
| Example 14 | | | | | | | | | | | | | |
| Synthesis | Pc-2 | — | — | mb-1 | 10 | mc-1/mc-2/mc-3 = 1/1/1 | 45 | md-3 | 45 | — | — | 8000 | 1.7 |
| Example 15 | | | | | | | | | | | | | |
| Synthesis | Pc-3 | ma-1 | 15 | — | — | mc-2/mc-3 = 1/1 | 30 | md-1 | 45 | rb-1 | 10 | 7800 | 1.7 |
| Example 16 | | | | | | | | | | | | | |
| Synthesis | Pc-4 | ma-1 | 15 | — | — | mc-2/mc-3 = 1/1 | 30 | md-1 | 35 | rb-1/mf-1 = 1/1 | 20 | 7600 | 1.7 |
| Example 17 | | | | | | | | | | | | | |
| Synthesis | Pc-5 | ma-1 | 15 | — | — | mc-2/mc-3 = 1/1 | 30 | md-1 | 35 | me-1/mf-1 = 1/1 | 20 | 8000 | 1.7 |
| Example 18 | | | | | | | | | | | | | |

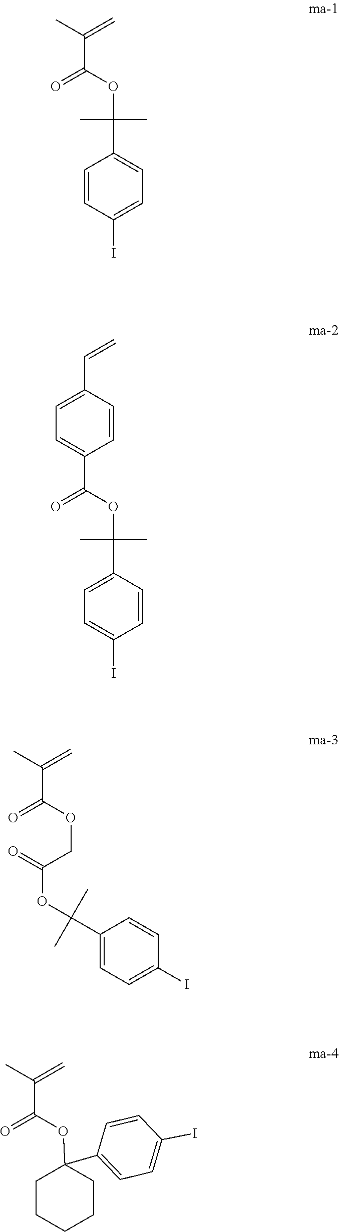 [SMILES: C=C(C)C(=O)OC(C)(C)c1ccc(I)cc1 ; C=Cc1ccc(C(=O)OC(C)(C)c2ccc(I)cc2)cc1 ; C=C(C)C(=O)OCC(=O)OC(C)(C)c1ccc(I)cc1 ; C=C(C)C(=O)OC1(c2ccc(I)cc2)CCCCC1]

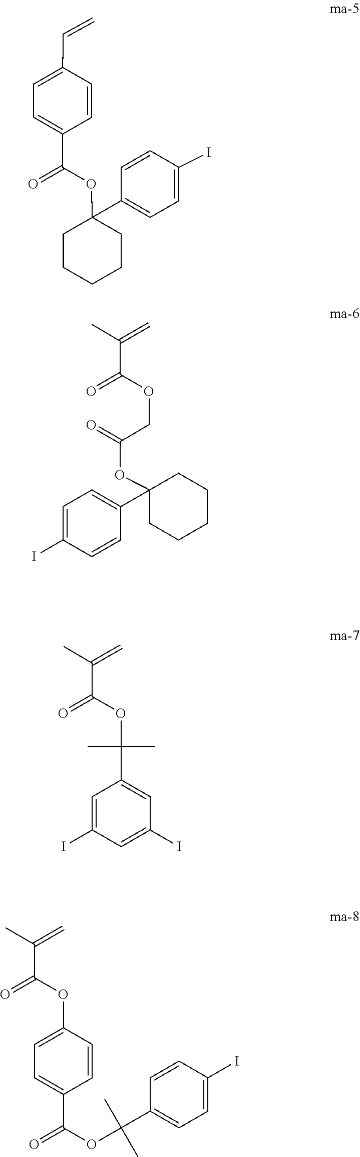

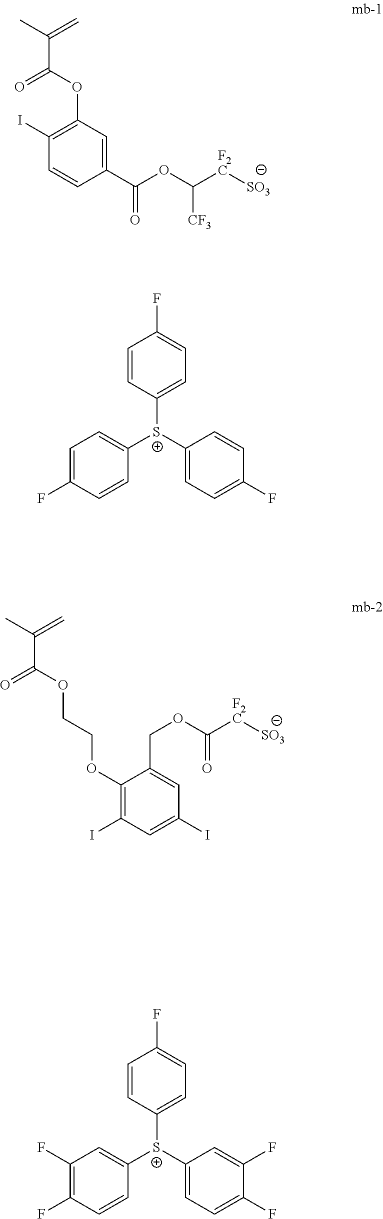

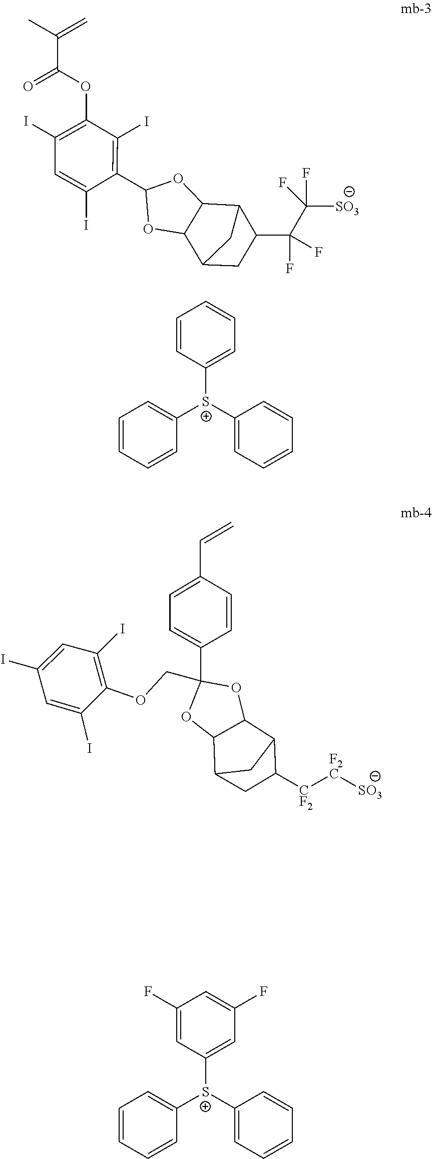

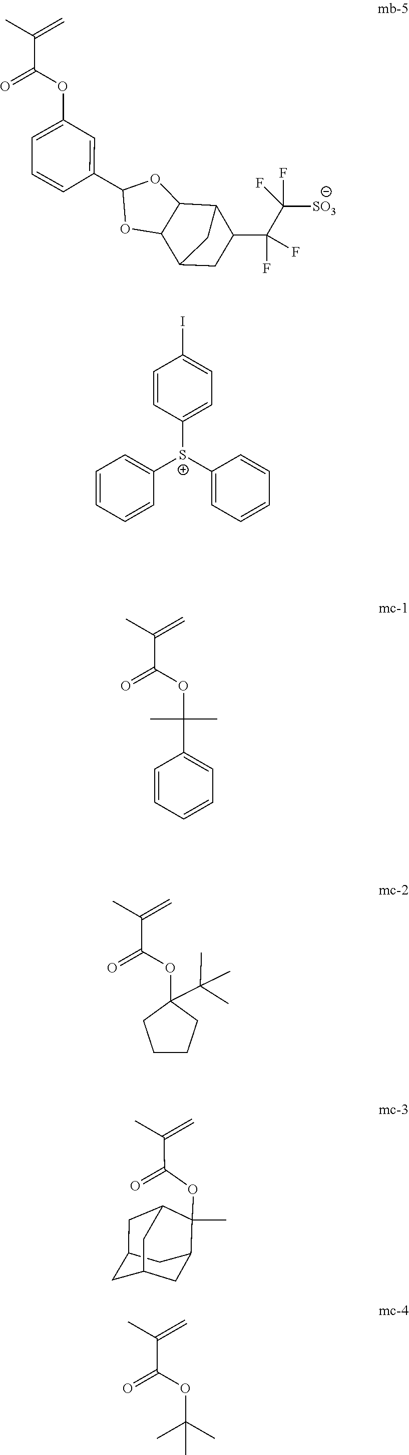

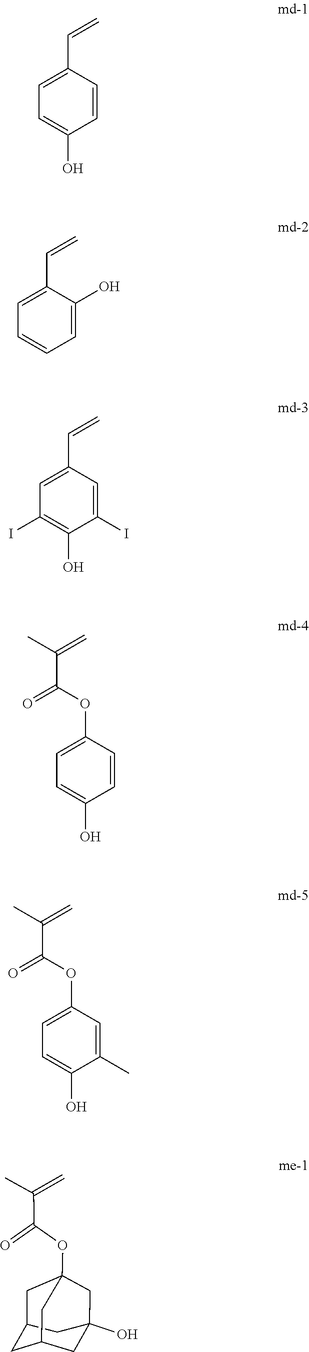

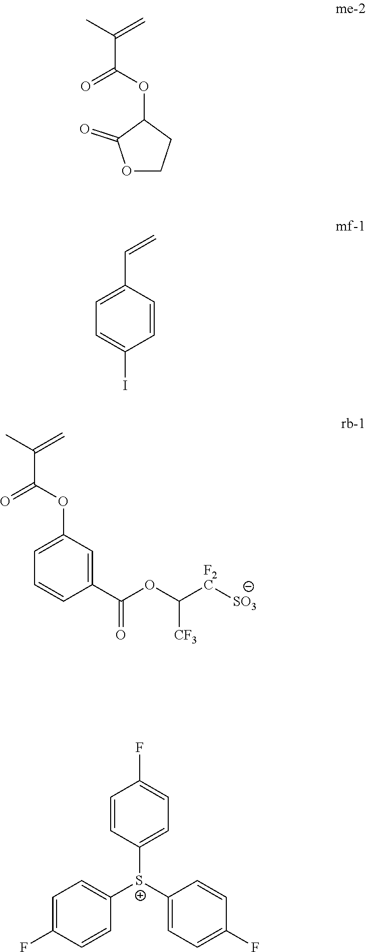

### Examples 1 to 14 and Comparative Examples 1 to 5

A radiation-sensitive resin composition was prepared by filtering, through a 0.2 μm-sized filter, a solution prepared by dissolving components, with the composition given in Table 2, in a solvent containing 100 ppm of FC-4430 manufactured by 3M as a surfactant dissolved therein. In the table, “-” indicates that the corresponding component was not used.

In Table 2, the components are as follows.

Organic solvent: PGMEA (propylene glycol monomethyl ether acetate)
GBL (γ-butyrolactone)
CHN (cyclohexanone)
PGME (propylene glycol monomethyl ether)
DAA (diacetone alcohol)
EL (ethyl lactate)

High fluorine-content resin F-1: Mw=8,900, Mw/Mn=2.0 (The numerical values attached to the structural units are molar ratios.)

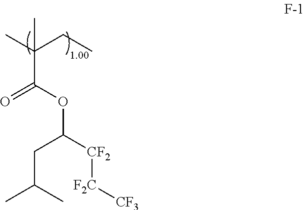

### [Evaluation of Sensitivity by EUV Exposure]

A composition for forming an antireflective film (“ARC66” manufactured by Brewer Science, Inc.) was applied onto a 12-inch silicon wafer using a spin coater (“CLEAN TRACK ACT12” manufactured by Tokyo Electron Limited), and then heated at 205° C. for 60 seconds to form an underlayer antireflective film having an average thickness of 10 nm. Each radiation-sensitive resin composition shown in Table 2 was applied onto the underlayer antireflection film using the spin coater, followed by performing prebaking at 130° C. for 60 seconds. Thereafter, cooling was performed at 23° C. for 30 seconds to form a resist film having an average thickness of 55 nm. This resist film was exposed to light using an EUV scanner (“NXE3300” (NA 0.33, σ 0.9/0.6, quadrupole illumination, hole pattern mask with a pitch of 46 nm on wafer and a bias of +20%) manufactured by ASML). PEB was performed on a hot plate at 120° C. for 60 seconds, and development was performed with a 2.38% by mass aqueous tetramethylammonium hydroxide (TMAH) solution for 30 seconds to form a resist pattern with a 23 nm hole and a 46 nm pitch. The exposure dose at which the resist pattern with a 23 nm hole and a 46 nm pitch was formed was defined as an optimum exposure dose (Eop), and the optimum exposure dose was defined as sensitivity (mJ/cm²).

### [Evaluation of CDU]

A resist pattern with a 23 nm hole and a 46 nm pitch was formed through the same operation as that described above by applying the exposure dose Eop determined above. The resist pattern formed was observed from the top of the pattern using a scanning electron microscope (“CG-5000” manufactured by Hitachi High-Technologies Corporation). The hole diameter was measured at 16 points in a range of 500 nm and the average value thereof was determined. In addition, the average value was measured at arbitrary 500 points in total. The 3 sigma value was determined from the distribution of the measurement values, and the 3 sigma value determined was taken as an evaluation value (nm) of CDU performance. The smaller an evaluation value of CDU performance is, the smaller the dispersion of hole diameter in a long period is and the better the CDU performance is. The results are shown in Table 2.

TABLE 2

| | | Radiation- | | | | | |
|---|---|---|---|---|---|---|---|
| | | sensitive acid | Acid diffusion | | High fluorine- | | |
| | Base resin | generator | controlling agent | Solvent | content resin | Sensitivity | CDU |
| | (parts by mass) | (parts by mass) | (parts by mass) | (parts by mass) | (parts by mass) | [mJ/cm²] | [nm] |
| Example 1 | P-1 | — | Q-1 | PGMEA/EL | F-1 | 14 | 2.2 |
| | (100) | | (5.0) | (2,000/500) | (3.0) | | |
| Example 2 | P-2 | — | Q-1 | PGMEA/EL | F-1 | 13 | 2.2 |
| | (100) | | (5.0) | (2,000/500) | (3.0) | | |
| Example 3 | P-3 | — | Q-2 | PGMEA/EL | F-1 | 15 | 2.1 |
| | (100) | | (5.0) | (2,000/500) | (3.0) | | |
| Example 4 | P-4 | — | Q-1 | PGMEA/EL | F-1 | 14 | 2.1 |
| | (100) | | (5.0) | (2,000/500) | (3.0) | | |
| Example 5 | P-5 | — | Q-1 | PGMEA/EL | F-1 | 14 | 2.2 |
| | (100) | | (5.0) | (2,000/500) | (3.0) | | |
| Example 6 | P-6 | — | Q-1 | PGMEA/CHN | — | 14 | 2.2 |
| | (100) | | (5.0) | (2,000/500) | | | |
| Example 7 | P-7 | — | Q-1 | PGMEA/GBL | — | 13 | 2.2 |
| | (100) | | (5.0) | (2,000/500) | | | |
| Example 8 | P-8 | PAG1 | Q-1 | PGMEA/PGME | F-1 | 13 | 2.0 |
| | (100) | (2.0) | (5.0) | (2,000/500) | (3.0) | | |
| Example 9 | P-9 | — | Q-3 | PGMEA/CHN/PGME | F-1 | 13 | 2.0 |
| | (100) | | (2.0) | (1,500/800/200) | (3.0) | | |
| Example 10 | P-10 | — | Q-1 | PGME/DAA | F-1 | 14 | 2.2 |
| | (100) | | (5.0) | (1,000/1,500) | (3.0) | | |
| Example 11 | P-11 | — | Q-1 | PGMEA/EL | — | 14 | 2.2 |
| | (100) | | (5.0) | (2,000/500) | | | |
| Example 12 | P-12 | — | Q-1 | PGMEA/GBL | — | 14 | 2.1 |
| | (100) | | (5.0) | (2,000/500) | | | |
| Example 13 | P-13 | — | Q-1 | PGMEA/GBL | — | 13 | 2.2 |
| | (100) | | (5.0) | (2,000/500) | | | |
| Example 14 | Pc-1/Pc-3 = 1/1 | — | Q-1 | PGMEA/EL | F-1 | 14 | 2.3 |
| | (100) | | (5.0) | (2,000/500) | (3.0) | | |
| Comparative | Pc-1 | — | Q-1 | PGMEA/EL | F-1 | 15 | 2.3 |
| Example 1 | (100) | | (5.0) | (2,000/500) | (3.0) | | |
| Comparative | Pc-2 | — | Q-1 | PGMEA/EL | — | 15 | 2.3 |
| Example 2 | (100) | | (5.0) | (2,000/500) | | | |
| Comparative | Pc-3 | — | Q-1 | PGMEA/EL | F-1 | 15 | 2.3 |
| Example 3 | (100) | | (5.0) | (2,000/500) | (3.0) | | |
| Comparative | Pc-4 | — | Q-1 | PGMEA/EL | F-1 | 15 | 2.3 |
| Example 4 | (100) | | (5.0) | (2,000/500) | (3.0) | | |
| Comparative | Pc-5 | — | Q-1 | PGMEA/EL | — | 14 | 2.4 |
| Example 5 | (100) | | (5.0) | (2,000/500) | | | |

The evaluation conducted for the resist patterns formed through the EUV exposure revealed that the radiation-sensitive resin compositions of Examples had good sensitivity and CDU performance.

### INDUSTRIAL APPLICABILITY

According to the radiation-sensitive resin composition and the pattern formation method described above, a resist pattern having good sensitivity to exposure light and superior CDU performance can be formed. Therefore, these can be suitably used for a machining process and the like of a semiconductor device in which micronization is expected to further progress in the future.

1: A radiation-sensitive resin composition comprising:
a radiation-sensitive acid generating resin comprising: a structural unit (I) comprising an acid-dissociable group; and a structural unit (II) comprising an organic acid anion moiety and an onium cation moiety; and
a solvent,
wherein the acid-dissociable group and the organic acid anion moiety each comprise an iodine-substituted aromatic ring structure.

2: The radiation-sensitive resin composition according to claim 1, wherein an aromatic ring in the iodine-substituted aromatic ring structure is a benzene ring.

3: The radiation-sensitive resin composition according to claim 1, wherein a number of iodine atoms in the iodine-substituted aromatic ring structure in the acid-dissociable group is 1 or 2.

4: The radiation-sensitive resin composition according to claim 1, wherein the structural unit (I) is represented by formula (1): 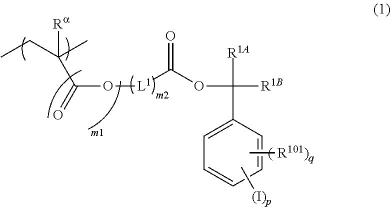
wherein in the formula (1),
R^{α} is a hydrogen atom, a fluorine atom, a methyl group, or a trifluoromethyl group;
L¹ is a divalent linking group;
R^{1A} and R^{1B} are each independently a monovalent chain hydrocarbon group having 1 to 10 carbon atoms or a monovalent alicyclic hydrocarbon group having 3 to 20 carbon atoms, or R^{1A} and R^{1B} taken together represent a divalent alicyclic group having 3 to 20 carbon atoms together with the carbon atom to which R^{1A} and R^{1B} are bonded;
R¹⁰¹ is a nitro group, a cyano group, a hydroxy group, an alkoxy group, or an amino group; when there are a plurality of R¹⁰¹s, the plurality of R¹⁰¹s are same as or different from each other;
m1 and m2 are each independently 0 or 1, provided that when m1 is 1, m2 is 1;
p is an integer of 1 to 3, and q is an integer of 0 to 3, provided that p+q is 5 or less.

5: The radiation-sensitive resin composition according to claim 1, wherein a content of the structural unit (I) to all structural units composing the radiation-sensitive acid generating resin is 5 mol % or more and 60 mol % or less.

6: The radiation-sensitive resin composition according to claim 1, wherein the radiation-sensitive acid generating resin comprises the organic acid anion moiety at a side chain portion.

7: The radiation-sensitive resin composition according to claim 1, wherein the organic acid anion moiety comprises at least one anion selected from the group consisting of a sulfonate anion, a carboxylate anion, and a sulfonimide anion.

8: The radiation-sensitive resin composition according to claim 1, wherein
the organic acid anion moiety comprises a sulfonate anion, and
a fluorine atom or a fluorinated hydrocarbon group is bonded to a carbon atom adjacent to the sulfonate anion.

9: The radiation-sensitive resin composition according to claim 1, wherein a number of iodine atoms in the iodine-substituted aromatic ring structure in the organic acid anion moiety is 1 to 4.

10: The radiation-sensitive resin composition according to claim 1, wherein a number of iodine atoms in the iodine-substituted aromatic ring structure in the organic acid anion moiety is 2, 3, or 4.

11: The radiation-sensitive resin composition according to claim 1, wherein the organic acid anion moiety comprises —O—, —CO—, a cyclic structure, or a combination thereof.

12: The radiation-sensitive resin composition according to claim 1, wherein the onium cation moiety is a fluorine-containing onium cation moiety comprising a fluorine atom.

13: The radiation-sensitive resin composition according to claim 1, wherein a content of the structural unit (II) to all structural units composing the radiation-sensitive acid generating resin is 1 mol % or more and 30 mol % or less.

14: The radiation-sensitive resin composition according to claim 1, wherein the radiation-sensitive acid generating resin further comprises a structural unit comprising a phenolic hydroxy group.

15: The radiation-sensitive resin composition according to claim 1, further comprising an acid diffusion controlling agent that generates an acid having a pKa higher than a pKa of an acid generated from the radiation-sensitive acid generating resin through irradiation with radiation.

16: A pattern forming method, comprising
directly or indirectly applying the radiation-sensitive resin composition according to claim 1 to a substrate to form a resist film,
exposing the resist film to light, and
developing the exposed resist film with a developer.

17: The pattern forming method according to claim 17, wherein the exposure is performed using extreme ultraviolet ray or an electron beam.
